(19) United States
(12) Patent Application Publication
(10) Pub. No.: US 2012/0043540 A1
(43) Pub. Date: Feb. 23, 2012

(54) Semiconductor device, method for manufacturing same, and display device

(76) Inventor: Tomohiro Kimura, Osaka (JP)

(21) Appl. No.: 13/138,496

(22) PCT Filed: Oct. 30, 2009
(86) PCT No.: PCT/JP2009/068702

§ 371 Date: Aug. 26, 2011

(30) Foreign Application Priority Data
Mar. 16, 2009 (JP) 2009-063147

(51) Int. Cl. H01L 29/04; H01L 21/22

(52) U.S. Cl. 257/49; 438/510; 257/E29.003; 257/E21.135

(57) ABSTRACT

The present invention provides a semiconductor device capable of suppressing a contact failure due to an increase in contact resistance, a production method of the semiconductor device, and a display device. The present invention provides a semiconductor device which includes a thin-film diode including a crystalline semiconductor layer which includes a cathode region and an anode region, a cathode electrode connected to the cathode region, and an anode electrode connected to the anode region, the thin-film diode, the cathode electrode, and the anode electrode being disposed on a substrate, and which is featured in that the crystalline semiconductor layer includes a first low-impurity-concentration region having an impurity concentration lower than the impurity concentration of the cathode region, in that the first low-impurity-concentration region is arranged adjacent to the cathode region, and in that the cathode electrode is in contact with an area of the cathode region, the area being within 3 μm from the boundary at which the cathode region is in contact with the first low-impurity-concentration region.

### TECHNICAL FIELD

The present invention relates to a semiconductor device, its production method, and a display device. More particularly, the present invention relates to a semiconductor device suitable for a middle-sized or small-sized display device including a touch panel, a production method of the semiconductor device, and a display device.

### BACKGROUND ART

In recent years, a display device provided with a touch panel has been developed for a mobile display device used in a portable telephone, a digital camera, or the like, and for a middle-sized or small-sized display device (display), such as an on-vehicle display device. Especially, a touch panel incorporating a thin-film transistor (TFT) as well as a photo sensor element has been developed.

Generally, a thin-film diode (TFD) is used as the photo sensor element. For example, a thin-film diode having a PIN structure is irradiated with light while a reverse bias is applied to the thin-film diode, and a photocurrent increased by the light is measured to detect the light.

Further, the silicon used for the semiconductor layer of a TFD and a TFT is generally classified into low-crystalline silicon (amorphous silicon) and high-crystalline silicon (polysilicon) according to the difference in the crystallinity. The amorphous silicon has advantages that it is inexpensive and can be easily formed into a film on an amorphous material and also on a material vulnerable to high temperature; however, a disadvantage is that it has a low mobility. On the other hand, polysilicon has mobility approximately double-digits higher than the mobility of amorphous silicon, and hence the performance, such as operation speed, of the TFT can be improved by using polycrystalline silicon for the semiconductor layer of the TFT.

In this connection, as a technique for stably and accurately measuring the amount of light, a thin-film diode is disclosed, which has a PIN structure using, as an active layer, a polysilicon formed on a glass substrate, and which is featured by including, in a same film, a p-region heavily doped with boron, an n-region heavily doped with phosphorus, and an i-region almost free of impurity, and is featured in that: the p-region is connected to an anode electrode and the n-region is connected to a cathode electrode; an n-region lightly doped with a donor material is provided between the i-region and the n-region; and a gate electrode is provided on the i-region and the n-region via an insulating film (see, for example, Patent Document 1).

Patent Document 1: Japanese Patent Laid-Open No. 2005-19636

### SUMMARY OF THE INVENTION

However, in the thin-film diode used for the photo sensor element, and the like, even with the technique described in Patent Document 1, the contact resistance between a cathode region and the cathode electrode connected thereto as well as the contact resistance between an anode region and the anode electrode connected thereto may be increased, and a failure (hereinafter also referred to as “contact failure”) due to an insufficient amount of current in the TFD may thereby occur. More specifically, in a production step of the TFD including the polycrystalline semiconductor layer, the cathode region and the anode region are usually formed by doping a high dose of impurities into the polycrystalline semiconductor layer with an ion implantation method, and then activating the implanted impurities by heat, or the like. The activation then recovers the crystal structure of the cathode region and the anode region, which has been damaged by the ion implantation. However, there have been cases where a variation in the production step causes insufficient crystal recovery by the activation in the cathode region and the anode region. The cases where a variation is caused in the production process include a case of the occurrence of unintentionally excessive ion implantation, a variation in the activation, and the like. Further, the factors causing the unintentionally excessive ion implantation include a variation in the implantation amount of impurities, a variation in the acceleration voltage at the time of ion implantation, a variation in the film thickness of the semiconductor layer subjected to the ion implantation, a variation in the film thickness of the insulating film formed on the semiconductor layer, and the like. Further, there has been a case where insufficient crystal recovery in the cathode region and the anode region causes the sheet resistance of the cathode region and the anode region to increase, and thereby the contact resistance between the cathode region and the cathode electrode, and the contact resistance between the anode region and the anode electrode are increased, resulting in a contact failure.

The present invention has been made in view of the above-described circumstances. An object of the present invention is to provide a semiconductor device capable of suppressing the contact failure due to the increase in the contact resistance, and to provide a production method of the semiconductor device, and a display device.

### DISCLOSURE OF THE INVENTION

The present inventors have examined various semiconductor devices capable of suppressing the contact failure due to the increase in the contact resistance, and directed attention to the starting point of the crystal recovery in the cathode region and the anode region at the time of activation. Then, the present inventors first clarified the following points about the conventional semiconductor device.

Here, the state of the cathode region at the time of ion implantation of high dose of impurities and at the time of activation will be described with reference to FIG. 24. FIG. 24 shows a case where, in the step for forming the cathode region and the anode region of the conventional semiconductor device, conditions are set so that the peak of the depth profile of impurities doped by the ion implantation method exists in the insulating film on the semiconductor layer. Note that the state of the anode region is the same as the state of the cathode region and hence the description about the anode region is omitted. As shown in FIG. 24(a), in the conventional semiconductor device, a high dose of impurities 117 are doped by the ion implantation method into a crystalline semiconductor layer 102 on a substrate 101 through an insulating film 103. Thereby, the region of the crystalline semiconductor layer 102 except the region of the crystalline semiconductor layer 102 overlapping a resist 115 is subjected to the ion implantation. Therefore, a channel region 105 under the resist 115 is not subjected to the ion implantation, and a region of the crystalline semiconductor layer 102, which is to be a cathode region 108n, is subjected to the ion implantation. In FIG. 24(a), the difference in the gray level in the cathode region 108n represents the difference in crystallinity, and the region having a darker gray level has a higher degree of crystal damage and a lower degree of crystallinity. In FIG. 24(a), the conditions are set so that the peak of a depth profile 112 of the implanted impurities exists in the insulating film 103. Therefore, the degree of crystal damage of the cathode region 108n is gradually increased from the side of the substrate 101 to the side of the insulating film 103. That is, the region of the cathode region 108n adjacent to the insulating film 103 has a highest degree of crystal damage and a low degree of crystallinity. Meanwhile, the region of the cathode region 108n adjacent to the substrate 101 has a low degree of crystal damage and a high degree of crystallinity. Note that, in FIG. 24(a), the difference in crystallinity is represented by three gray levels, but in practice, the crystallinity is gradually changed as described above.

When the impurities 117 implanted into the cathode region 108n are activated by heat, or the like, the crystal recovery of the cathode region 108n occurs. Further, the crystal recovery proceeds from a high crystallinity region as a starting point. That is, in the conventional semiconductor device shown in FIG. 24(b), the region of the cathode region 108n adjacent to the substrate 101 mainly served as the starting point of the crystal recovery, and the crystal recovery proceeded in the direction shown by the hollow arrow. At this time, when the degree of the crystal damage in the crystalline semiconductor layer 102 was high due to a variation in the implantation amount of impurities, and the like, there was a case where the crystal recovery in the cathode region 108n was insufficient, resulting in an increase in the sheet resistance of the cathode region 108n. Further, there was a case where, due to the increase in the sheet resistance, the contact resistance between the cathode region 108n and the cathode electrode 109n, that is, the contact resistance of the portion (contact section 106n) of the cathode region 108n, the portion being in contact with the cathode electrode 109n, was increased. The present inventors found that these states result in the contact failure due to the reduction in the amount of current in the TFD.

In this way, when a region having a low degree of crystal damage (having a high degree of crystallinity) exists in the cathode region and the anode region, the crystal recovery in the cathode region and the anode region at the time of activation proceeds from the high crystallinity region as a starting point. Further, the more the degree of crystallinity of the region serving as the starting point is higher, the higher the activation rate becomes. Therefore, when a high dose of impurities are doped by the ion implantation method into the crystalline semiconductor layer, it is effective for increasing the activation rate and promoting the crystal recovery that a region having a low degree of crystal damage is formed in the semiconductor layer on the side of the substrate by reducing as much as possible the amount of impurity ions reaching the semiconductor layer on the side of the substrate by adjusting the acceleration voltage.

In addition, as a result of further investigation, the present inventors have come to consider that the crystal recovery, which has conventionally been insufficient in some cases, may be promoted in such a manner that a low-impurity-concentration region having an impurity concentration lower than the impurity concentration of the cathode region and the anode region is arranged adjacent to the cathode region and the anode region so that the low-impurity-concentration region having a high degree of crystallinity is added among a starting point of the crystal recovery at the time of activation.

Here, the results of the experiment performed by the present inventors in order to confirm the effect of the low-impurity-concentration region on the crystal recovery of the cathode region and the anode region at the time of activation will be mentioned with reference to FIGS. 25 to 27. In order to obtain a state in which the crystal recovery was insufficient at the time of activation, the present inventors produced a polysilicon with impurities intentionally excessively doped therein by the ion implantation method, and analyzed the states of the produced polysilicon before and after the activation by observation using an optical microscope and by Raman spectrum measurement. Further, as a comparative example, the measurement was also performed to an amorphous silicon not subjected to the ion implantation and the activation. As shown in FIG. 25(a), a high dose of impurities were doped by the ion implantation method to a polysilicon 30, so that a region (ion implantation region 31) with the impurities implanted therein was formed in the square region having one side of about 20 μm and shown by the dotted lines. That is, the ion implantation region 31 corresponds to the cathode region and the anode region in which the degree of crystal damage is high. At this time, the region surrounding the ion implantation region 31 was formed as the region (no ion implantation region 37) into which impurities are not implanted.

Then, the point P located substantially at the center of the ion implantation region 31, and the point L located in the no ion implantation region 37 were measured by Raman spectroscopy, and the measured results were compared with the measured result of an amorphous silicon 33 shown in FIG. 26(b). As shown in FIG. 25(b), the Raman spectrum at the point Q exhibited a pattern having a peak at about 520 cm⁻¹ corresponding to high crystalline silicon, while similar to the pattern of the Raman spectrum of the amorphous silicon 33 shown in FIG. 26(b). Accordingly, the Raman spectrum at the point P exhibited a broad pattern it was confirmed that the crystal damage was caused in the ion implantation region 31 into which a high dose of impurities were implanted.

In contrast, after the activation, the area of the dark gray-level region was reduced in the region of the ion implantation region 31 adjacent to the no ion implantation region 37 as shown in FIG. 27(a).

Then, in FIG. 27(a), the point P located substantially at the center of the ion implantation region 31, the point S located in the ion implantation region 31 within about 2 μm inward from the no ion implantation region 37, and the point R located in the middle between the point P and the point S were measured by Raman spectroscopy. As a result of the measurement, as shown in FIG. 27(b), the Raman spectra at the point P and the point R were spectra in which a broad pattern similar to the pattern of the Raman spectrum of the amorphous silicon 33 shown in FIG. 26(b), and a peak at about 520 cm⁻¹ corresponding to the high crystalline silicon were superimposed upon each other. On the other hand, the Raman spectrum at the point S exhibited a pattern which is similar to the pattern of the Raman spectrum at the point Q shown in FIG. 25(b) and which has a peak at about 520 cm⁻¹ corresponding to the high crystalline silicon. Thereby, it could be confirmed that the crystallinity of the region, such as the region at the point S, which is included in the ion implantation region 31, and which is within about 2 μm inward from the no ion implantation region 37, is recovered by the activation to a level equivalent to the crystallinity of the no ion implantation region 37.

Thus, as a result of further investigation, the present inventors found that, when a low-impurity-concentration region is arranged adjacent to the cathode region and/or the anode region so that the low-impurity-concentration region is added among a starting point of crystal recovery at the time of activation, the crystal recovery in the cathode region and/or the anode region is promoted, and the crystal recovery in the cathode region and/or the anode region, which has been insufficient in the conventional technique in some cases, can be sufficient. The present inventors came to realize that the above-described problems can be completely solved by this method, and reached the present invention.

That is, the present invention provides a semiconductor device (hereinafter also referred to as “first semiconductor device according to the present invention”) which include a thin-film diode having a crystalline semiconductor layer which include a cathode region and an anode region; a cathode electrode connected to the cathode region; and an anode electrode connected to the anode region, the thin film diode, the cathode electrode, and the anode electrode being disposed on a substrate, wherein the crystalline semiconductor layer includes a first low-impurity-concentration region having an impurity concentration lower than the impurity concentration of the cathode region, the first low-impurity-concentration region is arranged adjacent to the cathode region, and the cathode electrode is in contact with an area of the cathode region, the area being within 3 μm from the boundary at which the cathode region is in contact with the first low-impurity-concentration region.

The crystal recovery of the cathode region and the anode region at the time of activation occurs regardless of the gradient of the degree of crystal damage (crystal defect). However, when there is a region having a lower degree of crystal damage, the crystal recovery is promoted from the region as a starting point. Therefore, in the first semiconductor device according to the present invention, the crystal recovery occurs in the cathode region at the time of activation not only from the region having a low degree of crystal damage in the cathode region (for example, the region of the cathode region on the side of the substrate), but also from the first low-impurity-concentration region adjacent to the cathode region. That is, the crystal recovery in the cathode region is greatly promoted as compared with the conventional device. Thereby, the crystal recovery can be sufficient in the cathode region at the time of activation, so that the sheet resistance of the cathode region can be reduced. As a result, the contact resistance can be reduced, and hence the generation of the contact failure can be suppressed. Note that, when the region serving as the starting point of the crystal recovery at the time of activation has a lower degree of crystal damage, the effect of promoting the crystal recovery is increased more.

Further, the sheet resistance and the contact resistance of the cathode region are reduced, and thereby the on-resistance of the semiconductor device is reduced, so that a failure due to the reduction in the on-current (hereinafter referred to as “Iₒₙ failure”) can be suppressed.

Further, as described above, the crystal recovery is particularly effectively achieved in an area of the cathode region, the area being within about 2 μm from the boundary at which the cathode region is in contact with the first low-impurity-concentration region. Therefore, the contact resistance between the cathode region and the cathode electrode can be further reduced when the cathode electrode is in contact with the area of the cathode region, the area being within 3 μm from the boundary at which the cathode region is in contact with the first low-impurity-concentration region.

The configuration of the first semiconductor device of the present invention is not especially limited as long as it essentially includes such components. The first semiconductor device may or may not include other components.

Further, the present invention provides a semiconductor device (hereinafter also referred to as “second semiconductor device according to the present invention”) including a thin-film diode having a crystalline semiconductor layer which includes a cathode region and an anode region; a cathode electrode connected to the cathode region; and an anode electrode connected to the anode region, the thin film diode, the cathode electrode, and the anode electrode being disposed on a substrate, wherein the crystalline semiconductor layer includes a second low-impurity-concentration region having an impurity concentration lower than the impurity concentration of the anode region, the second low-impurity-concentration region is arranged adjacent to the anode region, and the anode electrode is in contact with an area of the anode region, the area being within 3 μm from the boundary at which the anode region is in contact with the second low-impurity-concentration region.

The crystal recovery of the cathode region and the anode region at the time of activation occurs regardless of the gradient of the crystal damage (crystal defect). However, when there is a region having a lower degree of crystal damage, the crystal recovery is promoted from the region. Therefore, in the second semiconductor device according to the present invention, the crystal recovery occurs in the anode region at the time of activation not only from the region having a low degree of crystal damage in the anode region (for example, the region of the anode region on the side of the substrate), but also from the second low-impurity-concentration region adjacent to the anode region. That is, the crystal recovery in the anode region is greatly promoted as compared with the conventional device. Thereby, the crystal recovery can be sufficient in the anode region at the time of activation, so that the sheet resistance of the anode region can be reduced. As a result, the contact resistance between the anode region and the anode electrode can be reduced, along with hence the contact failure can be suppressed. Note that, when the region serving as the starting point of the crystal recovery at the time of activation has a lower degree of crystal damage, the effect of promoting the crystal recovery is increased more.

Further, as the sheet resistance and the contact resistance of the anode region are reduced, the on-resistance of the semiconductor device is reduced, and thereby the Iₒₙ failure can be suppressed.

Further, as described above, the crystal recovery is particularly effectively achieved in the area of the anode region within about 2 μm from the boundary at which the anode region is in contact with the second low-impurity-concentration region. Therefore, the contact resistance between the anode region and the anode electrode can be further reduced when the anode electrode is in contact with the area of the anode region within 3 μm from the boundary at which the anode region is in contact with the second low-impurity-concentration region.

The configuration of the second semiconductor device of the present invention is not especially limited as long as it essentially includes such components. The second semiconductor device may or may not include other components.

Further, the present invention provides a semiconductor device (hereinafter also referred to as “third semiconductor device according to the present invention”) including a thin-film diode having a crystalline semiconductor layer which includes a cathode region and an anode region, a cathode electrode connected to the cathode region, and an anode electrode connected to the anode region, the thin-film diode, the cathode electrode, and the anode electrode being disposed on a substrate, wherein the crystalline semiconductor layer includes a first low-impurity-concentration region having an impurity concentration lower than the impurity concentration of the cathode region, and a second low-impurity-concentration region having an impurity concentration lower than the impurity concentration of the anode region, the first low-impurity-concentration region is arranged adjacent to the cathode region, the second low-impurity-concentration region is arranged adjacent to the anode region, the cathode electrode is in contact with an area of the cathode region within 3 μm from the boundary at which the cathode region is in contact with the first low-impurity-concentration region, and the anode electrode is in contact with an area of the anode region within 3 μm from the boundary at which the anode region is in contact with the second low-impurity-concentration region.

With the third semiconductor device according to the present invention, the contact failure can be effectively suppressed in both sides of the cathode electrode and the anode electrode similarly to the first and second semiconductor devices according to the present invention.

The configuration of the third semiconductor device of the present invention is not especially limited as long as it essentially includes such components. The third semiconductor device may or may not include other components.

Further, the present invention provides a semiconductor device (hereinafter also referred to as “fourth semiconductor device according to the present invention” which includes a thin-film diode having a crystalline semiconductor layer which include a cathode region and an anode region; a cathode electrode connected to the cathode region; and an anode electrode connected to the anode region, the thin film diode, the cathode electrode, and the anode electrode being disposed on a substrate, wherein the crystalline semiconductor layer includes a first low-impurity-concentration region having an impurity concentration lower than the impurity concentration of the cathode region, the first low-impurity-concentration region is arranged adjacent to the cathode region, and the cathode electrode is in contact with the cathode region and the first low-impurity-concentration region.

The crystal recovery of the cathode region and the anode region at the time of activation occurs regardless of the gradient of crystal damage (crystal defect). However, when there is a region having a lower degree of crystal damage, the crystal recovery is promoted from the region. Therefore, in the fourth semiconductor device according to the present invention, the crystal recovery occurs in the cathode region at the time of activation not only from the region having a low degree of crystal damage in the cathode region (for example, the region of the cathode region on the side of the substrate), but also from the first low-impurity-concentration region adjacent to the cathode region. That is, the crystal recovery in the cathode region is greatly promoted as compared with the conventional device. Thereby, the crystal recovery can be sufficient in the cathode region at the time of activation, so that the sheet resistance of the cathode region can be reduced. As a result, the contact resistance between the cathode region and the cathode electrode can be reduced, and hence the contact failure can be suppressed. Note that, when the region serving as the starting point of the crystal recovery at the time of activation has a lower degree of crystal damage, the effect of promoting the crystal recovery is increased more.

Further, the sheet resistance and the contact resistance of the cathode region are reduced, and thereby the on-resistance of the semiconductor device is reduced, so that the failure due to the reduction in the on-current can be suppressed.

Further, the crystal recovery is particularly effectively achieved in the region of the cathode region in the vicinity of the first low-impurity-concentration region, and the region becomes a cathode region having particularly high crystallinity. Therefore, when the cathode electrode is in contact with both the cathode region and the first low-impurity-concentration region, the contact resistance between the cathode region and the cathode electrode can be further reduced. Thereby, even if misalignment occurs when a contact hole for connecting the cathode electrode to the cathode region is formed, the cathode electrode can be surely arranged in the area of the cathode region, in which area the crystal recovery is sufficient. Therefore, even if a production apparatus having low alignment accuracy is used, the contact resistance can be more surely reduced, so that the contact failure and the Iₒₙ failure can be more surely suppressed.

The configuration of the fourth semiconductor device of the present invention is not especially limited as long as it essentially includes such components. The fourth semiconductor device may or may not include other components.

Further, the present invention provides a semiconductor device (hereinafter also referred to as “fifth semiconductor device according to the present invention”) including a thin-film diode having a crystalline semiconductor layer which includes a cathode region and an anode region; a cathode electrode connected to the cathode region; and an anode electrode connected to the anode region, the thin film diode, the cathode electrode, and the anode electrode being disposed on a substrate, wherein the crystalline semiconductor layer includes a second low-impurity-concentration region having an impurity concentration lower than the impurity concentration of the anode region, the second low-impurity-concentration region is arranged adjacent to the anode region, and the anode electrode is in contact with the anode region and the second low-impurity-concentration region.

The crystal recovery of the cathode region and the anode region at the time of activation occurs regardless of the gradient of the degree of crystal damage (crystal defect). However, when there is a region having a lower degree of crystal damage, the crystal recovery is promoted from the region. Therefore, in the fifth semiconductor device according to the present invention, the crystal recovery occurs in the anode region at the time of activation not only from the region having a low degree of crystal damage in the anode region (for example, the region of the anode region on the side of the substrate), but also from the second low-impurity-concentration region adjacent to the anode region. That is, the crystal recovery in the anode region is greatly promoted as compared with the conventional device. Thereby, the crystal recovery can be sufficient in the anode region at the time of activation, so that the sheet resistance of the anode region can be reduced. As a result, the contact resistance between the anode region and the anode electrode can be reduced, and hence the contact failure can be suppressed. Note that, when the region serving as the starting point of the crystal recovery at the time of activation has a lower degree of crystal damage, the effect of promoting the crystal recovery is increased more.

Further, as the sheet resistance and the contact resistance of the anode region are reduced, the on-resistance of the semiconductor device is reduced, and thereby the Iₒₙ failure can be suppressed.

Further, the crystal recovery is particularly effectively achieved in the region of the anode region on the side of the second low-impurity-concentration region, and the region becomes an anode region having particularly high crystallinity. Therefore, when the anode electrode is in contact with both the anode region and the second low-impurity-concentration region, the contact resistance between the anode region and the anode electrode can be further reduced. Thereby, even if misalignment occurs when a contact hole for connecting the anode electrode to the anode region is formed, the anode electrode can be surely arranged in the area of the anode region, in which area the crystal recovery is sufficient. Therefore, even if a production apparatus having low alignment accuracy is used, the contact resistance can be more surely reduced, so that the contact failure and the Iₒₙ failure can be more surely suppressed.

The configuration of the fifth semiconductor device of the present invention is not especially limited as long as it essentially includes such components. The fifth semiconductor device may or may not include other components.

Further, the present invention provides a semiconductor device (hereinafter also referred to as “sixth semiconductor device according to the present invention”) including a thin-film diode having a crystalline semiconductor layer which includes a cathode region and an anode region; a cathode electrode connected to the cathode region; and an anode electrode connected to the anode region, the thin-film diode, the cathode electrode, and the anode electrode being disposed on a substrate, wherein the crystalline semiconductor layer includes a first low-impurity-concentration region having an impurity concentration lower than the impurity concentration of the cathode region, and a second low-impurity-concentration region having an impurity concentration lower than the impurity concentration of the anode region, the first low-impurity-concentration region is arranged adjacent to the cathode region, the second low-impurity-concentration region is arranged adjacent to the anode region, the cathode electrode is in contact with the cathode region and the first low-impurity-concentration region, and the anode electrode is in contact with the anode region and the second low-impurity-concentration region.

With the sixth semiconductor device according to the present invention, the generation of the contact failure in both sides of the cathode electrode and the anode electrode can be effectively suppressed similarly to the fourth and fifth semiconductor devices according to the present invention.

The configuration of the sixth semiconductor device of the present invention is not especially limited as long as it essentially includes such components. The sixth semiconductor device may or may not include other components.

Further, the present invention provides a semiconductor device (hereinafter also referred to as “seventh semiconductor device according to the present invention”) including a thin-film diode having a crystalline semiconductor layer which includes a cathode region and an anode region; a cathode electrode connected to the cathode region; and an anode electrode connected to the anode region, the thin film diode, the cathode electrode, and the anode electrode being disposed on a substrate, wherein the crystalline semiconductor layer includes a first low-impurity-concentration region having an impurity concentration lower than the impurity concentration of the cathode region, the first low-impurity-concentration region is arranged adjacent to the cathode region, the cathode region includes a high crystallinity cathode region which is located on the side of the first low-impurity-concentration region and has crystallinity higher than the crystallinity of an area of the cathode region not located on the side of the first low-impurity-concentration region, and the cathode electrode is in contact with the high crystallinity cathode region.

The crystal recovery of the cathode region and the anode region at the time of activation occurs regardless of the gradient of the degree of crystal damage (crystal defect). However, when there is a region having a lower degree of crystal damage, the crystal recovery is promoted from the region. Therefore, in the seventh semiconductor device according to the present invention, the crystal recovery occurs in the cathode region at the time of activation not only from the region having a low degree of crystal damage in the cathode region (for example, the region of the cathode region on the side of the substrate), but also from the first low-impurity-concentration region adjacent to the cathode region. That is, the crystal recovery in the cathode region is greatly promoted as compared with the conventional device. Thereby, the crystal recovery can be sufficient in the cathode region at the time of activation, so that the sheet resistance of the cathode region can be reduced. As a result, the contact resistance between the cathode region and the cathode electrode can be reduced, and hence the contact failure can be suppressed. Note that, when the region serving as the starting point of the crystal recovery at the time of activation has a lower degree of crystal damage, the effect of promoting the crystal recovery is increased more.

Further, the sheet resistance and the contact resistance of the cathode region are reduced, and thereby the on-resistance of the semiconductor device is reduced, so that the Iₒₙ failure can be suppressed.

Further, as the cathode electrode is in contact with the high crystallinity cathode region having high crystallinity, the contact resistance between the cathode region and the cathode electrode can be further reduced.

The configuration of the seventh semiconductor device of the present invention is not especially limited as long as it essentially includes such components. The seventh semiconductor device may or may not include other components.

Further, the present invention provides a semiconductor device (hereinafter also referred to as “eighth semiconductor device according to the present invention”) including a thin-film diode having a crystalline semiconductor layer which includes a cathode region and an anode region; a cathode electrode connected to the cathode region; and an anode electrode connected to the anode region, the thin film diode, the cathode electrode, and the anode electrode being disposed on a substrate, wherein the crystalline semiconductor layer includes a second low-impurity-concentration region having an impurity concentration lower than the impurity concentration of the anode region, the second low-impurity-concentration region is arranged adjacent to the anode region, the anode region includes a high crystallinity anode region which is located on the side of the second low-impurity-concentration region and has crystallinity higher than the crystallinity of an area of the anode region not located on the side of the second low-impurity-concentration region, and the anode electrode is in contact with the high crystallinity anode region.

The crystal recovery of the cathode region and the anode region at the time of activation occurs regardless of the gradient of the degree of crystal damage (crystal defect). However, when there is a region having a lower degree of crystal damage, the crystal recovery is promoted from the region. Therefore, in the eighth semiconductor device according to the present invention, the crystal recovery occurs in the anode region at the time of activation not only from the region having a low degree of crystal damage in the anode region (for example, the region of the anode region on the side of the substrate), but also from the second low-impurity-concentration region adjacent to the anode region. That is, the crystal recovery in the anode region is greatly promoted as compared with the conventional device. Thereby, the crystal recovery can be sufficient in the anode region at the time of activation, so that the sheet resistance of the anode region can be reduced. As a result, the contact resistance between the anode region and the anode electrode can be reduced, and hence the contact failure can be suppressed. Note that, when the region serving as the starting point of the crystal recovery at the time of activation has a lower degree of crystal damage, the effect of promoting the crystal recovery is increased more.

Further, the sheet resistance and the contact resistance of the anode region are reduced, and thereby the on-resistance of the semiconductor device is reduced, so that the Iₒₙ failure can be suppressed.

Further, as the anode electrode is in contact with the high crystallinity anode region having high crystallinity, the contact resistance between the anode region and the anode electrode can be further reduced.

The configuration of the eighth semiconductor device of the present invention is not especially limited as long as it essentially includes such components. The eighth semiconductor device may or may not include other components.

Further, the present invention provides a semiconductor device (hereinafter also referred to as “ninth semiconductor device according to the present invention”) including a thin-film diode having a crystalline semiconductor layer which includes a cathode region and an anode region; a cathode electrode connected to the cathode region; and an anode electrode connected to the anode region, the thin-film diode, the cathode electrode, and the anode electrode being disposed on a substrate, wherein the crystalline semiconductor layer includes a first low-impurity-concentration region having an impurity concentration lower than the impurity concentration of the cathode region, and a second low-impurity-concentration region having an impurity concentration lower than the impurity concentration of the anode region, the first low-impurity-concentration region is arranged adjacent to the cathode region, the second low-impurity-concentration region is arranged adjacent to the anode region, the cathode region includes a high crystallinity cathode region located on the side of the first low-impurity-concentration region and having crystallinity higher than the crystallinity of the area of the cathode region, the area being not located on the side of the first low-impurity-concentration region, the anode region includes a high crystallinity anode region located on the side of the second low-impurity-concentration region and having crystallinity higher than the crystallinity of the area of the anode region, the area being not located on the side of the second low-impurity-concentration region, the cathode electrode is in contact with the high crystallinity cathode region, and the anode electrode is in contact with the high crystallinity anode region.

With the ninth semiconductor device according to the present invention, similarly to the seventh and eighth semiconductor devices according to the present invention, the contact failure can be effectively suppressed on both sides of the cathode electrode and the anode electrode.

The configuration of the ninth semiconductor device of the present invention is not especially limited as long as it essentially includes such components. The ninth semiconductor device may or may not include other components.

Further, the present invention provides a semiconductor device (hereinafter also referred to as “tenth semiconductor device according to the present invention”) including a thin-film diode having a crystalline semiconductor layer which includes a cathode region and an anode region; a cathode electrode connected to the cathode region; and an anode electrode connected to the anode region, the thin film diode, the cathode electrode, and the anode electrode being disposed on a substrate, wherein the crystalline semiconductor layer includes a first low-impurity-concentration region having an impurity concentration lower than the impurity concentration of the cathode region, and the first low-impurity-concentration region is arranged adjacent to the cathode region except the region of the cathode region on the anode region side.

The crystal recovery of the cathode region and the anode region at the time of activation occurs regardless of the gradient of the degree of crystal damage (crystal defect). However, when there is a region having a lower degree of crystal damage, the crystal recovery is promoted from the region. Therefore, in the tenth semiconductor device according to the present invention, the crystal recovery occurs in the cathode region at the time of activation not only from the region having a low degree of crystal damage in the cathode region (for example, the region of the cathode region on the side of the substrate), but also from the first low-impurity-concentration region adjacent to the cathode region. That is, the crystal recovery in the cathode region is greatly promoted as compared with the conventional device. Thereby, the crystal recovery can be sufficient in the cathode region at the time of activation, so that the sheet resistance of the cathode region can be reduced. As a result, the contact resistance between the cathode region and the cathode electrode can be reduced, and hence the contact failure can be suppressed. Note that, when the region serving as the starting point of the crystal recovery at the time of activation has a lower degree of crystal damage, the effect of promoting the crystal recovery is increased more.

Further, the sheet resistance and the contact resistance of the cathode region are reduced, and thereby the on-resistance of the semiconductor device is reduced, so that the Iₒₙ failure can be suppressed.

Further, the first low-impurity-concentration region is arranged adjacent to the cathode region except the region of the cathode region on the side of the anode region, and hence the first low-impurity-concentration region can be arranged on the outer side of the current path between the cathode region and the anode region. Therefore, it is possible to suppress reduction in the amount of the current of the thin-film diode due to the first low-impurity-concentration region.

The configuration of the tenth semiconductor device of the present invention is not especially limited as long as it essentially includes such components. The tenth semiconductor device may or may not include other components.

Further, the present invention provides a semiconductor device (hereinafter also referred to as “eleventh semiconductor device according to the present invention”) including a thin-film diode having a crystalline semiconductor layer which includes a cathode region and an anode region; a cathode electrode connected to the cathode region; and an anode electrode connected to the anode region, the thin film diode, the cathode electrode, and the anode electrode being disposed on a substrate, wherein the crystalline semiconductor layer includes a second low-impurity-concentration region having an impurity concentration lower than the impurity concentration of the anode region, and the second low-impurity-concentration region is arranged adjacent to the anode region except the region of the anode region on the cathode region side.

The crystal recovery of the cathode region and the anode region at the time of activation occurs regardless of the gradient of the degree of crystal damage (crystal defect). However, when there is a region having a lower degree of crystal damage, the crystal recovery is promoted from the region. Therefore, in the eleventh semiconductor device according to the present invention, the crystal recovery occurs in the anode region at the time of activation not only from the region having a low degree of crystal damage in the anode region (for example, the region of the anode region on the side of the substrate), but also from the second low-impurity-concentration region adjacent to the anode region. That is, the crystal recovery in the anode region is greatly promoted as compared with the conventional device. Thereby, the crystal recovery can be sufficient in the anode region at the time of activation, so that the sheet resistance of the cathode region can be reduced. As a result, the contact resistance between the anode region and the anode electrode can be reduced, and hence the generation of the contact failure can be suppressed. Note that, when the region serving as the starting point of the crystal recovery at the time of activation has a lower degree of crystal damage, the effect of promoting the crystal recovery is increased more.

Further, the sheet resistance and the contact resistance of the anode region are reduced, and thereby the on-resistance of the semiconductor device is reduced, so that the Iₒₙ failure can be suppressed.

Further, the second low-impurity-concentration region is arranged adjacent to the anode region except the region of the anode region on the side of the cathode region, and hence the second low-impurity-concentration region can be arranged on the outer side of the current path between the cathode region and the anode region. Therefore, it is possible to suppress that the amount of current of the thin-film diode is reduced due to the second low-impurity-concentration region.

The configuration of the eleventh semiconductor device of the present invention is not especially limited as long as it essentially includes such components. The eleventh semiconductor device may or may not include other components.

Further, the present invention provides a semiconductor device (hereinafter also referred to as “twelfth semiconductor device according to the present invention”) including a thin-film diode having a crystalline semiconductor layer which includes a cathode region and an anode region; a cathode electrode connected to the cathode region; and an anode electrode connected to the anode region, the thin-film diode, the cathode electrode, and the anode electrode being disposed on a substrate, wherein the crystalline semiconductor layer includes a first low-impurity-concentration region having an impurity concentration lower than the impurity concentration of the cathode region, and a second low-impurity-concentration region having an impurity concentration lower than the impurity concentration of the anode region, the first low-impurity-concentration region is arranged adjacent to the cathode region except the region of the cathode region on the anode region side, and the second low-impurity-concentration region is arranged adjacent to the anode region except the region of the anode region on the cathode region side.

With the twelfth semiconductor device according to the present invention, similarly to the tenth and eleventh semiconductor devices according to the present invention, the generation of the contact failure can be effectively suppressed on both sides of the cathode electrode and the anode electrode.

The configuration of the twelfth semiconductor device of the present invention is not especially limited as long as it essentially includes such components. The twelfth semiconductor device may or may not include other components.

The first to twelfth semiconductor devices according to the present invention may be suitably employed in combination.

More specifically, in the fourth, sixth, seventh, ninth, tenth and twelfth semiconductor devices according to the present invention, the cathode electrode may be in contact with an area of the cathode region within 3 μm from the boundary at which the cathode region is in contact with the first low-impurity-concentration region.

In the fifth, sixth, eighth, ninth, eleventh and twelfth semiconductor devices according to the present invention, the anode electrode may be in contact with an area of the anode region within 3 μm from the boundary at which the anode region is in contact with the second low-impurity-concentration region.

In the first, third, seventh, ninth, tenth and twelfth semiconductor devices according to the present invention, the cathode electrode may be in contact with the cathode region and the first low-impurity-concentration region.

In the second, third, eighth, ninth, eleventh and twelfth semiconductor devices according to the present invention, the anode electrode may be in contact with the anode region and the second low-impurity-concentration region.

In the first, third, fourth, sixth, tenth and twelfth semiconductor devices according to the present invention, the cathode region may include a high crystallinity cathode region located on the side of the first low-impurity-concentration region and having crystallinity higher than the crystallinity of the area of the cathode region, the area being not located on the side of the first low-impurity-concentration region, and the cathode electrode may be in contact with the high crystallinity cathode region.

In the second, third, fifth, sixth, eleventh and twelfth semiconductor devices according to the present invention, the anode region may include a high crystallinity anode region located on the side of the second low-impurity-concentration region and having crystallinity higher than the crystallinity of the area of the anode region, the area being not located on the side of the second low-impurity-concentration region, and the anode electrode may be in contact with the high crystallinity anode region.

In the first, third, fourth, sixth, seventh and ninth semiconductor devices according to the present invention, the first low-impurity-concentration region may be arranged adjacent to the cathode region except the region of the cathode region on the anode region side.

In the second, third, fifth, sixth, eighth and ninth semiconductor devices according to the present invention, the second low-impurity-concentration region may be arranged adjacent to the anode region except the region of the anode region on the cathode region side.

Preferable embodiments of the first to twelfth semiconductor devices of the present invention are mentioned in more detail below. The following embodiments may be employed in combination.

Each of the first low-impurity-concentration region and the second low-impurity-concentration region is a region to which impurities are not added (for example, by ion implantation) at a dose substantially the same as the dose in the cathode region and the anode region. Each of the first low-impurity-concentration region and the second low-impurity-concentration region may be a region to which a low dose of impurities are added, or a region (no ion implantation region) to which no impurity is added. More specifically, from the following viewpoints, it is preferred that the impurity concentrations of the first low-impurity-concentration region and the second low-impurity-concentration region are 50% or less (preferably 10% or less) of the impurity concentrations of the cathode region and the anode region, respectively. Thereby, the crystallinity of the first low-impurity-concentration region and the second low-impurity-concentration region can be enhanced, so as to increase the effect that the crystal recovery in the cathode region and the anode region is promoted using the first low-impurity-concentration region and the second low-impurity-concentration region as starting points, respectively. Note that, when the impurity concentration of each of the first low-impurity-concentration region and the second low-impurity-concentration region exceeds 50%, there is a case where the effect of the first low-impurity-concentration region and the second low-impurity-concentration region serving as the starting points of the crystal recovery cannot be sufficiently exhibited.

The first low-impurity-concentration region and the second low-impurity-concentration region may be arranged at locations in the vertical direction (film thickness direction) of the cathode region and the anode region, respectively, if possible. However, it is preferred that the first low-impurity-concentration region and the cathode region are arranged in a same plane, and that the second low-impurity-concentration region and the anode region are arranged in a same plane. Thereby, the first low-impurity-concentration region and the second low-impurity-concentration region can be easily formed by using a photoresist, or the like.

The crystalline semiconductor layer may include a first contact section which is a portion in contact with the cathode electrode, and in a plan view of the substrate, the first low-impurity-concentration region may be arranged along the outer periphery of the first contact section except the outer periphery of the first contact section on the anode region side. Thereby, the crystal recovery of the cathode region around the first contact section can be efficiently promoted, so that the contact resistance can be further reduced and the contact failure can be suppressed. Further, the on-resistance of the semiconductor device can be further reduced, so that the Iₒₙ failure can be further suppressed. From the same viewpoint, in a plan view of the substrate, the first low-impurity-concentration region may be formed into a shape having a recess (for example, a U-shape), and the recessed section may be arranged along the outer periphery of the first contact section.

From the same viewpoint, the crystalline semiconductor layer may include a second contact section which is a portion in contact with the anode electrode, and in a plan view of the substrate, the second low-impurity-concentration region may be arranged along the outer periphery of the second contact section except the outer periphery of the second contact section on the cathode region side. Further, in a plan view of the substrate, the second low-impurity-concentration region may be formed into a shape having a recess (for example, a U-shape), and the recessed section may be arranged along the outer periphery of the second contact section.

The crystalline semiconductor layer may include a first contact section which is a portion in contact with the cathode electrode, and in a plan view of the substrate, the first low-impurity-concentration region may be arranged along a current path between the first contact section and the anode region. Thereby, the crystal recovery of the cathode region around the current path between the first contact section and the anode region can be promoted. Therefore, the sheet resistance of the cathode region in the region serving as the current path between the first contact section and the anode region can be reduced. Therefore, the on-resistance of the semiconductor device can be reduced, and the Iₒₙ failure can be further suppressed. Note that the thin-film diode usually includes two contact sections arranged opposite to each other (the first contact section and a second contact section that is a portion of the crystalline semiconductor layer, the portion being in contact with the anode electrode), and current (on current) flows between the two contact sections. That is, a current path is formed between the two contact sections. Therefore, from the same viewpoint as that in the above-described embodiment, the crystalline semiconductor layer may include the first contact section and the second contact section which are arranged opposite to each other, and in a plan view of the substrate, the first low-impurity-concentration region may be arranged along the region sandwiched between the first contact section and the second contact section.

Further, from the same viewpoint, the crystalline semiconductor layer may include the second contact section which is the portion in contact with the anode electrode, and in a plan view of the substrate, the second low-impurity-concentration region may be arranged along a current path between the second contact section and the cathode region. Also, the crystalline semiconductor layer may include the first contact section and the second contact section which are arranged opposite to each other, and in a plan view of the substrate, the second low-impurity-concentration region may be arranged along the region sandwiched between the first contact section and the second contact section.

The crystalline semiconductor layer may include the first contact section which is the portion in contact with the cathode electrode, and in a plan view of the substrate, the first low-impurity-concentration region may be arranged along the current path between the first contact section and the anode region and may also be arranged along the outer periphery of the first contact section except the outer periphery of the first contact section on the anode region side. Thereby, the crystal recovery of the cathode region around the current path between the first contact section and the anode region can be promoted. Therefore, the sheet resistance of the cathode region in the region serving as the current path between the first contact section and the anode region can be reduced. Further, the crystal recovery of the cathode region around the first contact section can be efficiently promoted, and hence the contact resistance can be further reduced. Therefore, the contact resistance can be further reduced, and thereby the contact failure can be further suppressed. Moreover, the on-resistance of the semiconductor device can be further reduced and the Iₒₙ failure can be further suppressed. Further, similarly to the above-described case, the crystalline semiconductor layer may include the first contact section and the second contact section which are arranged opposite to each other, and in a plan view of the substrate, the first low-impurity-concentration region may be arranged along the region sandwiched between the first contact section and the second contact section, and may also be arranged along the outer periphery of the first contact section except the outer periphery of the first contact section on the anode region side.

Further, from the same viewpoint, the crystalline semiconductor layer may include the second contact section which is the portion in contact with the anode electrode, and in a plan view of the substrate, the second low-impurity-concentration region may be arranged along the current path between the second contact section and the anode region, and may also be arranged along the outer periphery of the second contact section except the outer periphery of the second contact section on the cathode region side. Further, the crystalline semiconductor layer may include the first contact section and the second contact section which are arranged opposite to each other. In a plan view of the substrate, the second low-impurity-concentration region may be arranged along the region sandwiched between the first contact section and the second contact section, and may also be arranged along the outer periphery of the second contact section except the outer periphery of the second contact section on the cathode region side.

The semiconductor device may include an insulating film provided on the crystalline semiconductor layer, and a first resist provided on a region of the insulating film, the region overlapping the first low-impurity-concentration region (hereafter also referred to as first embodiment). Thereby, the first low-impurity-concentration region can be easily formed in the region of the crystalline semiconductor layer, the region being masked by the first resist. Further, the region masked by the first resist can be specified, and hence the inspection and analysis of the shape of the first low-impurity-concentration region, and the inspection and analysis of the alignment accuracy, and the like, can be easily performed.

Further, from the same viewpoint, the semiconductor device may include the insulating film provided on the crystalline semiconductor layer, and a second resist provided on a region of the insulating film, the region overlapping the second low-impurity-concentration region (hereafter also referred to as second embodiment).

Each of the first resist and the second resist may be residues of a resist left after removing the resist in a production step, that is, may be resist residues. Note that the remaining degree of the resist (for example, the film thickness of resist residues) can be usually controlled by suitably selecting the material of the resist, the removing method, and the like.

The semiconductor device may include the insulating film provided on the crystalline semiconductor layer, and may be configured such that the region of the insulating film overlapping the first low-impurity-concentration region is connected to the region of the insulating film overlapping the cathode region, and such that at least one of the film thickness and the film quality of the insulating film may be different between the region of the insulating film overlapping the first low-impurity-concentration region and the region of the insulating film overlapping the cathode region. Thereby, the concentration of the impurities added to the crystalline semiconductor layer can be adjusted by make use of at least one of the film thickness difference and the film quality difference of the continuous insulating film. Therefore, the first low-impurity-concentration region can be easily formed at the region of the crystalline semiconductor layer, the region overlapping the region of the insulating film having a small film thickness and/or allowing impurities to easily pass therethrough.

Further, from the same viewpoint, the semiconductor device may include the insulating film provided on the crystalline semiconductor layer, and may be configured such that the region of the insulating film overlapping the second low-impurity-concentration region is connected to the region of the insulating film overlapping the anode region, and such that at least one of the film thickness and the film quality of the insulating film may be different between the region of the insulating film overlapping the second low-impurity-concentration region and the region of the insulating film overlapping the anode region.

As an example of the case where the film quality is different, there can be listed an embodiment (for example, an embodiment with a small amount of structural defects) in which the insulating film in the region overlapping the first low-impurity-concentration region (or the second low-impurity-concentration region) is more dense than the insulating film in the region overlapping the cathode region (or the anode region). Such embodiment can be formed by making the film formation conditions, such as the temperature, the gas flow rate, and the applied voltage, different for each of the regions.

The semiconductor device may include the insulating film provided on the crystalline semiconductor layer, and may be configured such that the insulating film in the region overlapping the first low-impurity-concentration region includes a plurality of insulating films stacked together (hereafter also referred to as third embodiment). Thereby, a structure provided with the insulating film having a film thickness difference can be easily formed, and hence the concentration of the impurities added to the crystalline semiconductor layer can be easily adjusted by using the film thickness difference of the insulating film. Therefore, the first low-impurity-concentration region can be easily formed in the region of the crystalline semiconductor layer, the region overlapping the region in which the film thickness of the insulating film is large (the region in which the plurality of insulating films are stacked).

Further, from the same viewpoint, the semiconductor device may include the insulating film provided on the crystalline semiconductor layer, and may be configured such that the insulating film in the region overlapping the second low-impurity-concentration region includes a plurality of insulating films stacked together (hereafter also referred to as fourth embodiment).

The crystalline semiconductor layer may also include a channel region arranged between the anode region and the cathode region. Thereby, the present invention can be used suitably for a TFD having a PIN structure.

On the other hand, the crystalline semiconductor layer does not need to include the channel region arranged between the anode region and the cathode region. Thereby, the present invention can be used suitably for a TFD having a PN structure.

In the first, third, fourth, sixth, seventh and ninth semiconductor devices according to the present invention, it is preferred that the first low-impurity-concentration region is arranged between the cathode region and the anode region. Thereby, the first low-impurity-concentration region can be made to function similarly to an LDD of a TFT, and hence the leakage current can be suppressed.

Further, at this time, it is preferred that the thin-film diode does not include a conductive layer in the region which is located between the crystalline semiconductor layer and the layers of the cathode electrode and the anode electrode (excluding, however, the region in the contact hole or the through hole), and which, in a plan view of the substrate, overlaps the crystalline semiconductor layer. That is, the thin-film diode includes a first insulating layer provided on the crystalline semiconductor layer, and a second insulating layer provided on the first insulating layer, and also the cathode electrode and the anode electrode are provided on the second insulating layer. The thin-film diode does not need to include a conductive layer which is provided immediately above the first insulating layer and which overlaps the crystalline semiconductor layer. Thereby, the size of the device can be reduced, and the crystal recovery of the crystalline semiconductor layer can be homogeneous.

Further, from the same viewpoint, in each of the second, third, fifth, sixth, eighth and ninth semiconductor devices according to the present invention, it is preferred that the second low-impurity-concentration region is arranged between the cathode region and the anode region.

In this case as well, it is preferred that the thin-film diode does not include a conductive layer in the region which is located between the crystalline semiconductor layer and the layers of the cathode electrode and the anode electrode (excluding, however, the region in the contact hole or the through hole), and which, in a plan view of the substrate, overlaps the crystalline semiconductor layer. That is, the thin-film diode includes a first insulating layer provided on the crystalline semiconductor layer, and a second insulating layer provided on the first insulating layer, and also the cathode electrode and the anode electrode are provided on the second insulating layer. The thin-film diode does not need to include a conductive layer which is provided immediately above the first insulating layer and which overlaps the crystalline semiconductor layer. Thereby, the size of the device can be reduced, and the crystal recovery of the crystalline semiconductor layer can be homogeneous.

In the tenth and twelfth semiconductor devices according to the present invention, the first contact section, which is the portion of the crystalline semiconductor layer in contact with the cathode electrode, may overlap the first low-impurity-concentration region. Thereby, the region of the cathode region, which is adjacent to the first low-impurity-concentration region, and in which the crystal recovery is greatly promoted, can be more surely arranged in correspondence with the first contact section. As a result, the contact resistance can be more surely reduced, and the contact failure and the Iₒₙ failure can be more surely suppressed.

Further, from the same viewpoint, in the eleventh and twelfth semiconductor devices according to the present invention, the second contact section, which is the portion of the crystalline semiconductor layer in contact with the anode electrode, may overlap the second low-impurity-concentration region.

Further, the present inventions also provides a production method of the first, third, fourth, sixth, seventh, ninth, tenth and twelfth semiconductor devices according to the first embodiment of the present invention, the production method including a step of patterning the first resist on the insulating film, and a step of adding impurities to the crystalline semiconductor layer through the insulating film by using the first resist as a mask (hereinafter also referred to as “first semiconductor device production method according to the present invention”). Thereby, the first low-impurity-concentration region can be easily formed in the region of the crystalline semiconductor layer, the region being masked by the first resist, without increasing the number of steps as compared with the embodiment using the film thickness difference of the insulating film.

Further, the present invention also provides a production method of the second, third, fifth, sixth, eighth, ninth, eleventh and twelfth semiconductor devices according to the second embodiment of the present invention, the production method including a step of patterning the second resist on the insulating film, and a step of adding impurities to the crystalline semiconductor layer through the insulating film by using the second resist as a mask (hereinafter also referred to as “second semiconductor device production method according to the present invention”). Thereby, the second low-impurity-concentration region can be easily formed in the region of the crystalline semiconductor layer, the region being masked by the second resist, without increasing the number of steps as compared with the embodiment using the film thickness difference of the insulating film.

Further, the present invention also provides a production method of the first, third, fourth, sixth, seventh, ninth, tenth and twelfth semiconductor devices according to the third embodiment of the present invention, the production method including; a step of patterning a first insulating film on the region in which the first low-impurity-concentration region of the crystalline semiconductor layer is to be formed; a step of covering the crystalline semiconductor layer and the first insulating film to form a second insulating film; and a step of adding impurities to the crystalline semiconductor layer through the first insulating film and the second insulating film (hereinafter also referred to as “third semiconductor device production method according to the present invention”). Thereby, the insulating film configured to have the film thickness difference can be easily formed, and hence the concentration of impurities added to the crystalline semiconductor layer can be easily adjusted by using the film thickness difference of the insulating film. Therefore, the first low-impurity-concentration region can be easily formed in the region of the crystalline semiconductor layer, the region overlapping the region in which the insulating film has a large thickness (the region in which the first insulating film and the second insulating film are stacked).

Further, the present invention also provides a production method of the second, third, fifth, sixth, eighth, ninth, eleventh and twelfth semiconductor devices according to the fourth embodiment of the present invention, the production method including: a step of patterning a first insulating film on the region in which the second low-impurity-concentration region of the crystalline semiconductor layer is to be formed; a step of covering the crystalline semiconductor layer and the first insulating film to form a second insulating film; and a step of adding impurities to the crystalline semiconductor layer through the first insulating film and the second insulating film (hereinafter also referred to as “fourth semiconductor device production method according to the present invention”). Thereby, the insulating film configured to have the film thickness difference can be easily formed, and hence the concentration of impurities added to the crystalline semiconductor layer can be easily adjusted by using the film thickness difference of the insulating film. Therefore, the second low-impurity-concentration region can be easily formed in the region of the crystalline semiconductor layer, the region overlapping the region in which the insulating film has a large thickness (the region in which the first insulating film and the second insulating film are stacked).

Note that the first to fourth semiconductor device production methods according to the present invention are not especially limited as long as these steps are included. The production methods may or may not include other steps. Further, the first to fourth semiconductor device production methods according to the present invention may be employed in combination.

In the first to fourth semiconductor device production methods according to the present invention, the method for adding impurities to the crystalline semiconductor layer is not limited in particular, and, for example, an ion implantation method, an ion doping method, and the like, can be used. Among the methods, it is preferred to use the ion implantation method from a viewpoint of more easily controlling the addition amount of impurities and the depth profile of added impurities.

Further, the present invention also provides a display device including one of the first to twelfth semiconductor devices according to the present invention. Further, the present invention also provides a display device including the semiconductor device produced by one of the first to fourth semiconductor device production methods according to the present invention. Thereby, the semiconductor device capable of suppressing the contact failure can be used for a display device, and hence it is possible to realize a display device which has a high non-defective rate and high reliability, and in which the power consumption can be reduced.

### Effects of the Invention

With the semiconductor device, the production method of the semiconductor device and the display device according to the present invention, the contact failure due to the increase in the contact resistance can be suppressed.

### BRIEF DESCRIPTION OF THE DRAWING(S)

FIGS. 1(a) to 1(e) are cross-sectional schematic views showing a semiconductor device of embodiment 1 in production steps;

FIG. 2 is a schematic cross-sectional view showing the vicinity of a cathode region or an anode region of a TFD provided in the semiconductor device of embodiment 1, while FIG. 2(a) shows a state at the time of doping a high dose of impurities by an ion implantation method, and FIG. 2(b) shows a state at the time of activation;

FIG. 3 is a schematic plan view showing the vicinity of the cathode region or the anode region of the TFD provided in the semiconductor device of embodiment 1;

FIG. 4 is a schematic plan view showing the vicinity of the cathode region or the anode region of the TFD provided in the semiconductor device of embodiment 1, and showing a state at the time of doping, by the ion implantation method, a high dose of impurities under a condition different from the condition in FIG. 2;

FIG. 5 is a schematic cross-sectional view showing a modification of the TFD provided in the semiconductor device of embodiment 1;

FIG. 6 is a schematic plan view showing the vicinity of the cathode region or the anode region of the modification of the TFD provided in the semiconductor device of embodiment 1;

FIG. 7 is a schematic view showing a modification of the TFD provided in the semiconductor device of embodiment 1, while FIG. 7(a) is a plan view, and FIG. 7(b) is a cross-sectional view along the line X1-Y1 line in FIG. 7(a);

FIG. 8 is a schematic cross-sectional view showing a modification of the semiconductor device of embodiment 1;

FIG. 9 is a schematic plan view showing the vicinity of the cathode region or the anode region of the modification of the TFD provided in the semiconductor device of embodiment 1;

FIGS. 10(a) and 10(b) are schematic cross-sectional views showing a modification of the semiconductor device of embodiment 1 in the production steps;

FIG. 11 is a schematic cross-sectional view showing a modification of the TFD provided in the semiconductor device of embodiment 1;

FIG. 12 is a schematic cross-sectional view showing a modification of the TFD provided in the semiconductor device of embodiment 1;

FIG. 13 is a schematic cross-sectional view showing a modification of the TFD provided in the semiconductor device of embodiment 1;

FIG. 14 is a schematic plan view showing the vicinity of the cathode region or the anode region of the modification of the TFD provided in the semiconductor device of embodiment 1;

FIG. 15 is a schematic cross-sectional view showing a modification of the TFD provided in the semiconductor device of embodiment 1;

FIG. 16 is a schematic cross-sectional view showing a modification of the TFD provided in the semiconductor device of embodiment 1;

FIG. 17 is a schematic cross-sectional view showing a modification of the TFD provided in the semiconductor device of embodiment 1;

FIG. 18 is a schematic view showing a contact resistance measuring element of embodiment 1, while FIG. 18(a) is a plan view, and FIG. 18(b) is a cross-sectional view along the line X2-Y2 in FIG. 18(a);

FIG. 19 is a schematic plan view showing the contact resistance measuring element of embodiment 1;

FIG. 20 is a schematic view showing a contact resistance measuring element of embodiment 2, while FIG. 19(a) is a plan view, and FIG. 19(b) is a cross-sectional view along the line X3-Y3 in FIG. 19(a);

FIG. 21 is a schematic plan view showing a contact resistance-measuring element of comparative example 1;

FIG. 22 is a schematic plan view showing a contact resistance-measuring element of comparative example 2;

FIG. 23 is a diagram obtained by plotting the contact resistance of the contact resistance measuring elements of embodiments 1 and 2, and comparative examples 1 and 2 (note that, in FIG. 23, E in the ordinate scale indicating the value of contact resistance means a power of ten, for example, means that 1E+02 corresponds to 1×10²);

FIG. 24 is a schematic cross-sectional view showing the vicinity of a cathode region of a TFD provided in a conventional semiconductor device, while FIG. 24(a) shows a state at the time of doping a high dose of impurities by the ion implantation method, and FIG. 24(b) shows a state at the time of activation;

FIG. 25(a) shows a state of polysilicon before activation observed by an optical microscope, while FIG. 25(b) shows Raman spectra of the polysilicon before activation;

FIG. 26(a) shows a state of amorphous silicon observed by the optical microscope, while FIG. 25(b) shows a Raman spectrum of the amorphous silicon; and

FIG. 27(a) shows a state of polysilicon after activation observed by the optical microscope, while FIG. 27(b) shows Raman spectra of the polysilicon after activation.

### MODES FOR CARRYING OUT THE INVENTION

The present invention will be mentioned in more detail referring to the drawings in the following embodiments, but is not limited to these embodiments.

In this specification, a source/drain region means a region which functions as a source and/or a drain of a TFT. That is, a crystalline semiconductor layer of a TFT usually has two source/drain regions which are arranged opposite to each other so as to sandwich a channel region, and which are configured such that, when one of the source/drain regions functions as a source, the other of the source/drain regions functions as a drain.

### Embodiment 1

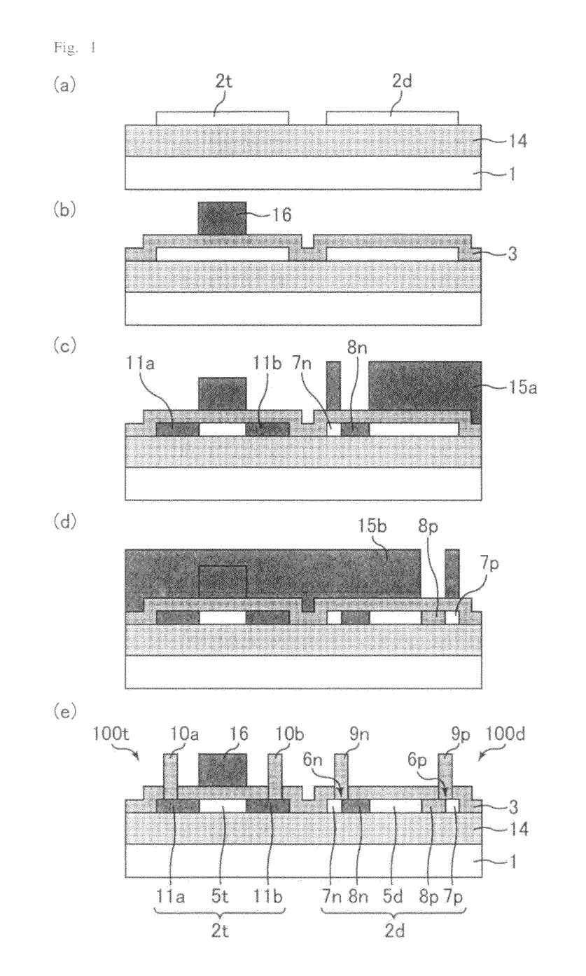

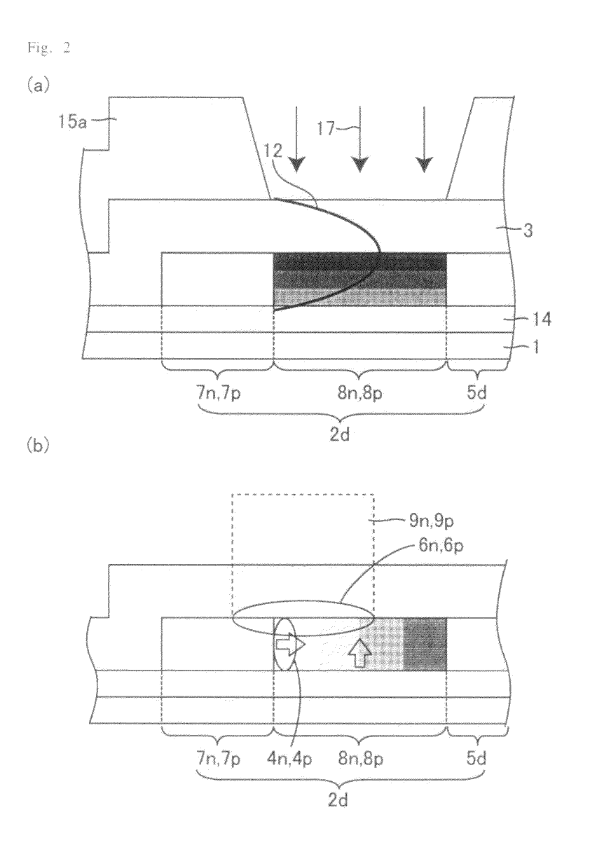

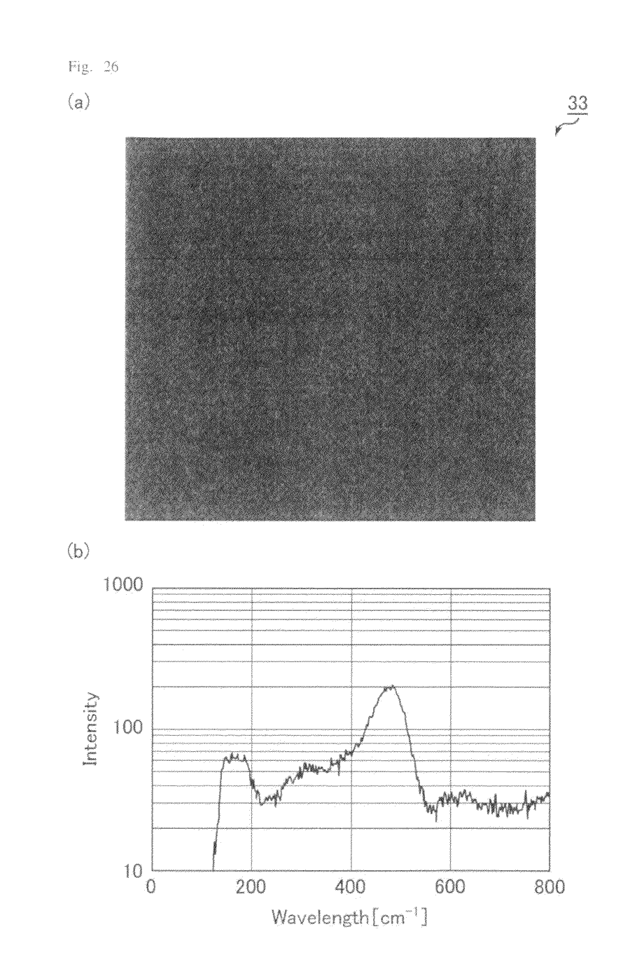

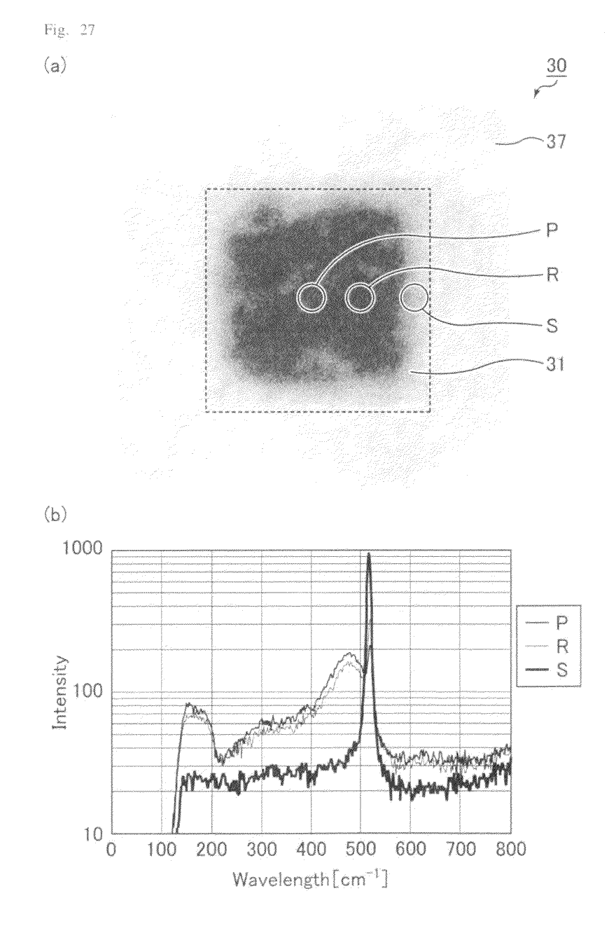

A configuration of a semiconductor device according to embodiment 1 will be mentioned with reference to FIGS. 1 to 3. Note that the difference in gray levels in a cathode region 8n or an anode region 8p in FIGS. 2(a) and 2(b) represents the difference in crystallinity. In a region having a darker gray level, the degree of crystal damage is higher and the crystallinity is lower. Further, similarly to the conventional semiconductor device shown in FIG. 24, FIG. 2 shows the case where, also in the semiconductor device of embodiment 1, conditions are set so that the peak of the depth profile of impurities doped by the ion implantation method exists in an insulating film.

As shown in FIG. 1(e), a semiconductor device according to the present embodiment includes a substrate 1, an underlayer 14 formed on the substrate 1, and a TFD 100d and a TFT 100t which are formed on the underlayer 14. The TFD 100d functions as a photo sensor.

The TFD 100d is a TFD having a PIN structure, and includes a crystalline semiconductor layer 2d formed on the underlayer 14, an insulating film 3 formed on the crystalline semiconductor layer 2d, an interlayer insulating film (not shown) formed on the insulating film 3, a cathode electrode 9n, and an anode electrode 9p. In this way, unlike the TFD described in Patent Document 1, the TFD 100d does not include a gate electrode.

The crystalline semiconductor layer 2d includes the cathode region 8n to which pentavalent atoms, such as phosphorus (P) atoms, are added (doped) at a high concentration (for example, about 1×10¹⁹ to about 1×10²¹ atm/cm³, preferably about 1×10²° atm/cm³), a channel region (i region) 5d almost free of impurities, the anode region 8p to which trivalent atoms, such as boron (B) atoms, are added (doped) at a high concentration (for example, about 1×10¹⁹ to about 1×10²¹ atm/cm³, preferably about 1×10²⁰ atm/cm³), a low-impurity-concentration region 7n having an impurity concentration lower than the impurity concentration of the cathode region 8n, and a low-impurity-concentration region 7p having an impurity concentration lower than the impurity concentration of the anode region 8p.

The low-impurity-concentration region 7n, the cathode region 8n, the channel region 5d, the anode region 8p, and the low-impurity-concentration region 7p are formed by the same semiconductor layer, and are adjacently arranged in this order in the same plane.

The cathode electrode 9n is in contact with the low-impurity-concentration region 7n and the cathode region 8n through a contact hole provided in the insulating film 3 and the interlayer insulating film. Thereby, the cathode electrode 9n is connected to the cathode region 8n. Further, the cathode electrode 9n is provided so as to be in contact with the area of the cathode region 8n within 3 μm (more preferably 2 nm) from the boundary at which the cathode region 8n is in contact with the low-impurity-concentration region 7n.

The anode electrode 9p is in contact with the low-impurity-concentration region 7p and the anode region 8p through a contact hole provided in the insulating film 3 and the interlayer insulating film. Thereby, the anode electrode 9p is connected to the anode region 8p. Further, the anode electrode 9p is provided so as to be in contact with the area of the anode region 8p within 3 μm (more preferably 2 nm) from the boundary at which the anode region 8p is in contact with the low-impurity-concentration region 7p.

In the following, the region of the crystalline semiconductor layer 2d, which is in contact with the cathode electrode 9n is denoted as a contact section 6n, and the region of the crystalline semiconductor layer 2d which is in contact with the anode electrode 9p is denoted as a contact section 6p.

The TFT 100t is a top gate type (planar type) TFT (Nch), and includes a crystalline semiconductor layer 2t formed on the underlayer 14, the insulating film 3 formed on the crystalline semiconductor layer 2t, a gate electrode 16 formed on the insulating film 3, an interlayer insulating film (not shown) formed on the insulating film 3 and the gate electrode 16, and source/drain electrodes 10a and 10b.

The crystalline semiconductor layer 2t includes a source/drain region 11a in which phosphorus is heavily doped, a channel region 5t, and a source/drain region 11b in which phosphorus is heavily doped.

The source/drain region 11a, the channel region 5t, and the source/drain region 11b are formed by the same semiconductor layer, and are adjacently arranged in this order in the same plane.

The source/drain electrodes 10a and 10b are in contact with the source/drain regions 11a and 11b through contact holes provided in the insulating film 3 and the interlayer insulating film, respectively. Thereby, the source/drain electrodes 10a and 10b are connected to the source/drain regions 11a and 11b, respectively.

The insulating film 3 is formed in common for the TFD 100d and the TFT 100t, and functions as a gate insulating film in the TFT 100t. Further, the interlayer insulating film is also provided in common for the TFD 100d and the TFT 100t.

In the following, the production steps of the semiconductor device according to the present embodiment will be mentioned. First, as shown in FIG. 1(a), the underlayer 14 is formed on one main surface of the substrate 1. As the underlayer 14, it is possible to use an insulating film (for example, SiO₂, SiN, SiNO), and the like, containing silicon. Further, the underlayer 14 may have a structure formed by stacking two or more layers of insulating films other than the single-layer structure of an insulating film. Further, in this case, a light-shielding layer may also be provided under semiconductor layers (crystalline semiconductor layers 2d and 2t) (and may be formed under or above the underlayer 14, and may also be formed between any of the layers of the underlayer 14 in the case where the underlayer 14 has a layered structure). More particularly, for example, the production steps may be performed such that a light-shielding film having a film thickness of 50 to 600 nm is formed (deposited), then a light-shielding layer is formed by patterning the light-shielding film into a desired shape by a photolithography step, thereafter the underlayer 14 is next formed, and next the semiconductor layers (crystalline semiconductor layers 2d and 2t) are formed. The material of the light shielding layer includes the same material as the material of the gate electrode 16 described below; specifically for example, high melting point metals, such as tungsten (W) and molybdenum (Mo), a semiconductor film, and the like.

The material of the substrate 1 is not limited in particular, and includes a glass substrate, a quartz substrate, a silicon substrate, a substrate formed by providing an insulating film on the surface of a metal plate or of a stainless plate, a plastic substrate having heat resistance enough to withstand the treatment temperature, and the like. Especially, the glass substrate used for a display device, such as a liquid crystal display device, is preferred.

Next, the island-shaped crystalline semiconductor layers 2d and 2t, each having a film thickness of 20 to 200 nm (preferably 30 to 70 nm), are formed. More specifically, an amorphous semiconductor film having an amorphous structure is formed by a sputtering technique, an LPCVD (Low Pressure CVD) method, or a plasma CVD (Chemical Vapor Deposition) method. Next, a crystalline semiconductor film is formed by crystallizing this amorphous semiconductor film by using laser. Then, the crystalline semiconductor layers 2d and 2t are formed by patterning the crystalline semiconductor film into a desired shape by a photolithography step. The material of the crystalline semiconductor layers 2d and 2t is not limited in particular, but silicon is preferred. That is, it is preferred that the crystalline semiconductor layers 2d and 2t include polysilicon.

In the crystallization step of the crystalline semiconductor layers 2d and 2t, a solid-phase growth step may be performed, in which a catalyst metal such as nickel (Ni) is applied to the amorphous semiconductor film and then heat treatment is performed. Thereby, a continuous grain boundary crystal silicon film (CG silicon film) can be formed as the crystalline semiconductor layers 2d and 2t.

Next, the insulating film 3 (first insulating layer) having a film thickness of 20 to 200 nm (preferably 30 to 120 nm) is formed. As the insulating film 3, an insulating film (for example, SiO₂ film, SiN film, SiNO film) containing silicon and formed by a plasma CVD method or a sputtering method can be preferably used. Further, the insulating film 3 may have, other than a single-layer structure, a structure formed by stacking a plurality of layers of insulating films made of a plurality of insulating materials.

Here, a low dose of impurities (trivalent atoms such as boron atoms or pentavalent atoms such as phosphorus atoms) may be doped in the crystalline semiconductor layer 2d, and especially in the channel region 5d, in order to perform intrinsic gettering for trapping impurities introduced along with contamination, and the like.

Further, in order to control the threshold voltage of the TFT, a low dose of trivalent atoms such as boron atoms may be doped in the crystalline semiconductor layer 2t by an ion implantation method.

Next, as shown in FIG. 1(b), the gate electrode 16 having a film thickness of 50 to 600 nm (preferably 100 to 500 nm) is formed. More specifically, a conductive film is formed by a sputtering method, and then the gate electrode 16 is formed by patterning the conductive film into a desired shape by a photolithography step. As the material of the gate electrode 16, a high melting point metal such as tantalum (Ta), tungsten (W), titanium (Ti), and molybdenum (Mo), or an alloy material or a compound material containing such high melting point metal as a main component is preferred. As a compound containing the high melting point metal as a main component, a nitride is preferred. The gate electrode 16 may have a structure formed by stacking conductive films which are formed of such materials.

Next, as shown in FIG. 1(c), a photoresist (resist) film is formed, and then a part of the photoresist film above the crystalline semiconductor layer 2t and a part of the photoresist film above the region in which the cathode region 8n is to be formed are removed by patterning the photoresist film. Thereby, the photoresist 15a is patterned on the region of the insulating film 3 overlapping the region in which the low-impurity-concentration region 7n, the channel region 5d, the anode region 8p, and the low-impurity-concentration region 7p are to be formed.

Next, as shown in FIGS. 2(a) and 2(b), a high dose of impurities (pentavalent atoms such as phosphorus atoms) 17 are doped into the crystalline semiconductor layers 2d and 2t through the insulating film 3 using the photoresist 15a and the gate electrode 16 as masks. Thereafter, by performing an activation treatment described below, the cathode region 8n and the low-impurity-concentration region 7n are formed in the crystalline semiconductor layer 2d, and also the source/drain regions 11a and 11b are formed in the crystalline semiconductor layer 2t.

More specifically, phosphorus ions at a dose amount of 5×10¹⁴ to 1×10¹⁶ cm⁻² (preferably 5×10¹⁴ to 5×10¹⁵ cm⁻²) are first doped as the impurities 17 by an ion implantation method at a relatively low acceleration voltage of 10 to 100 keV (preferably 20 to 80 keV). In the case of such conditions, the peak of the depth profile 12 of the doped impurities 17 exists in the region from within the insulating film 3 to the region of the crystalline semiconductor layers 2d and 2t on the side of the insulating film 3. Further, at this time, as shown by the curve of the depth profile 12, the degree of crystal damage of the cathode region 8n and the source/drain regions 11a and 11b is gradually increased from the side of the substrate 1 to the side of the insulating film 3 in many cases. In such a case, the degree of crystal damage becomes highest in the area of the cathode region 8n and the source/drain regions 11a and 11b, the area being adjacent to the insulating film 3, and hence the crystallinity becomes low in the area. Meanwhile, the degree of crystal damage is low in the area of the cathode region 8n and the source/drain regions 11a and 11b, the area being adjacent to the underlayer 14 on the side of the substrate 1, and hence the crystallinity becomes high in the area. In FIG. 2(a), the difference in the crystallinity is represented by three gray levels, but in practice, the crystallinity is changed gradually as described above.

Further, the conditions of the ion implantation may be changed so that the peak of the depth profile 12 of the doped impurities exists in the region other than the region described above. Specifically, when the sheet resistance of the cathode region 8n needs to be reduced in particular, the impurities 17 may be doped by the ion implantation method under the conditions such that the peak of the depth profile 12 of the doped impurities 17 exists in the region from within the cathode region 8n to within the underlayer 14 as shown in FIG. 4. In FIG. 4, the designation of the unmentioned components by reference numerals and characters is omitted.

On the other hand, from a viewpoint of more effectively avoiding that the crystal recovery of the cathode region 8n becomes insufficient at the time of activation, it is preferred that the peak of the depth profile 12 of the doped impurities 17 is set to the side of the upper layer of the cathode region 8n as described above.

When the peak of the depth profile 12 is generally deep in this way, more impurities are implanted and the sheet resistance is reduced, as compared with the case where the peak of the depth profile 12 is at a shallow level. On the other hand, when the peak of the depth profile 12 is generally at a shallow level, the crystal damage is less likely to occur and the crystal recovery is facilitated, as compared with the case where the peak of the depth profile 12 is deep.

Next, as shown in FIG. 1(d), after a photoresist (resist) film is formed, a portion of the photoresist film above the region in which the anode region 8p is to be formed is removed by patterning the photoresist film. Thereby, a photoresist 15b is patterned on the region of the insulating film 3, the region overlapping the region in which the crystalline semiconductor layer 2t, the low-impurity-concentration region 7n, the cathode region 8n, the channel region 5n, and the low-impurity-concentration region 7p are to be formed.

Next, similarly to the case shown in FIGS. 2(a) and 2(b), a high dose of impurities (trivalent atoms such as of boron atoms) 17 are doped into the crystalline semiconductor layer 2d through the insulating film 3 by using the photoresist 15b as a mask. Then, the anode region 8p and the low-impurity-concentration region 7p are formed in the crystalline semiconductor layer 2d by performing an activation treatment described below.

More specifically, boron ions at a dose amount of 5×10¹⁴ to 1×10¹⁶ cm⁻² (preferably 5×10¹⁴ to 5×10¹⁵ cm⁻²) are first doped as the impurities 17 by the ion implantation method at a relatively low acceleration voltage of 10 to 100 keV (preferably 20 to 80 keV). In the case of such conditions, the peak of the depth profile 12 of the doped impurities 17 exists in the region from within the insulating film 3 to the region of the crystalline semiconductor layers 2d on the side of the insulating film 3 in many cases. Further, at this time, as shown by the curve of the depth profile 12, the degree of crystal damage of the anode region 8p is gradually increased from the side of the substrate 1 to the side of the insulating film 3 in many cases. In such case, the degree of crystal damage becomes highest in the area of the anode region 8p, the area being adjacent to the insulating film 3, and hence the crystallinity becomes low in the area. On the other hand, the degree of crystal damage is low in the area of the anode region 8p, the area being adjacent to the underlayer 14 on the side of the substrate 1, and hence the crystallinity becomes high in the area.

The conditions of the ion implantation may be changed so that the peak of depth profile 12 of the doped impurities exists in an area other than the area described above. Specifically, when the sheet resistance of the anode region 8p needs to be particularly reduced, the impurities 17 may be doped by the ion implantation method under the conditions such that the peak of the depth profile 12 of the doped impurities 17 exists from within the anode region 8p to within the underlayer 14 as shown in FIG. 4.

Meanwhile, from the viewpoint of more effectively avoiding the insufficient crystal recovery of the anode region 8p at the time of activation, it is preferred that the peak of the depth profile 12 of the doped impurities 17 is set to the side of the upper layer of the anode region 8p as described above.

Next, the activation of the impurities 17 implanted into the crystalline semiconductor layers 2d and 2t and the crystal recovery of the crystalline semiconductor layers 2d and 2t are achieved by heating at 350 to 720° C. (preferably 400 to 700° C.) for 4 to 240 minutes. Thereby, the cathode region 8n, the anode region 8p, and the low-impurity-concentration regions 7n and 7p are formed in the crystalline semiconductor layer 2d, and also the source/drain regions 11a and 11b are formed in the crystalline semiconductor layer 2t. Further, the channel region 5d is formed in the region between the cathode region 8n and the anode region 8p, and also the channel region 5t is formed in the region of the crystalline semiconductor layer 2t, the region facing the gate electrode 16.

It is preferred that the photoresists 15a and 15b are removed after the ion implantation, but the residues (resist residues) of the photoresists 15 and 15b may exist on the region of the insulating film 3 overlapping the low-impurity-concentration regions 7n and 7p. When the resist residues are provided on the region of the insulating film 3 overlapping the low-impurity-concentration regions 7n and 7p, the region of the crystalline semiconductor layer 2d masked by the photoresists 15a and 15b can be specified, and hence the inspection and analysis of the shape of the low-impurity-concentration regions 7n and 7p, and the inspection and analysis of the alignment accuracy, and the like, can be easily performed.

Further, the above-described impurities 17 are not usually doped into the region of the crystalline semiconductor layer 2d masked by the photoresists 15a and 15b. For this reason, when a low dose of impurities used to perform the above-described intrinsic gettering are not doped into the crystalline semiconductor layer 2d, the low-impurity-concentration regions 7n and 7p formed by using the photoresists 15a and 15b are usually formed into a region (no ion implantation region) to which the impurities are not added. Alternately, for the purpose of performing intrinsic gettering, a low dose of impurities may be doped into the crystalline semiconductor layer 2d.

Thereafter, through the step of forming the interlayer insulating film (second insulating layer), and the step of forming the cathode electrode 9n, the anode electrode 9p, and the source/drain electrodes 10a and 10b, the semiconductor device according to the present embodiment can be produced as shown in FIG. 1(e). As the material of the interlayer insulating film, an insulating film (for example, SiO₂ film, SiN film, SiNO film) containing silicon and formed by a plasma CVD method or a sputtering method can be preferably used. Further, as the material of the cathode electrode 9n, the anode electrode 9p, and the source/drain electrodes 10a and 10b, it is preferred to use a low resistance metal such as aluminum (Al), copper (Cu), and silver (Ag), or an alloy material, a compound material, or the like, which contains one of the low resistance metals as a main component.

As described above, in the conventional semiconductor device, as shown in FIG. 24(b), the crystal recovery proceeds from, as a starting point, the area of the cathode region and the anode region having a low degree of crystal damage and located on the side of the substrate. Meanwhile, in the semiconductor device according to the present embodiment, the low-impurity-concentration regions 7n and 7p having a low degree of crystal damage are arranged adjacent to the cathode region 8n and the anode region 8p, respectively. For this reason, the low-impurity-concentration regions 7n and 7p are added among the starting points of crystal recovery, and hence the crystal recovery of the cathode region 8n and the anode region 8p at the time of activation proceeds not only from the side of the substrate 1 but also from the side of the low-impurity-concentration regions 7n and 7p as shown in FIG. 2(b). Thereby, the crystal recovery of the cathode region 8n and the anode region 8p can be further promoted as compared with the conventional semiconductor device. Further, the contact sections 6n and 6p can be arranged in the region in which the crystal recovery is achieved in the two directions from the side of the substrate 1 and from the side of the low-impurity-concentration region 7n or the low-impurity-concentration region 7p.

As described above, according to the present embodiment, the sheet resistance of the cathode region 8n and the anode region 8p can be reduced, and the contact resistance of the crystalline semiconductor layer 2d with the cathode electrode 9n and the anode electrode 9p can be reduced. As a result, the generation of contact failure can be suppressed.

Further, the sheet resistance and the contact resistance of the cathode region 8n and the anode region 8p are reduced, so that the on-resistance of the semiconductor device can be reduced, and the Iₒₙ failure due to the reduction in the ON-state current can be suppressed.

Further, even if the impurities are excessively implanted due to a variation in the production step, the increase in the contact resistance can be effectively suppressed.

Further, in the area of the cathode region 8n and the anode region 8p, the area being adjacent to the low-impurity-concentration regions 7n and 7p, the crystal recovery proceeds in the two directions from the side of the substrate 1 and from side of the low-impurity-concentration region 7n or the low-impurity-concentration region 7p, so that the crystallinity can be particularly improved.

More specifically, in the area of the cathode region 8n within about 2 μm from the boundary at which the cathode region 8n is in contact with the low-impurity-concentration region 7n, the crystal recovery occurs particularly more effectively than the area of the cathode region 8n not located on the side of the low-impurity-concentration region 7n. Thus, this area of the cathode region 8n on the side of the low-impurity-concentration region 7n is formed into an area having a relatively high degree of crystallinity (high crystallinity cathode region 4n). The high crystallinity cathode region 4n is an area which is adjacent to the low-impurity-concentration region 7n, or the low-impurity-concentration region 7p, and which has a higher degree of crystallinity than the degree of crystallinity of the region (for example, the central portion of the cathode region 8n) that is not adjacent to the low-impurity-concentration region 7n or the low-impurity-concentration region 7p. In this way, the high crystallinity cathode region 4n is an area which is adjacent to the low-impurity-concentration region 7n or the low-impurity-concentration region 7p, and which has a relatively high crystallinity in the cathode region 8n.

Similarly, in the area of the anode region 8p within about 2 μm from the boundary at which the anode region 8p is in contact with the low-impurity-concentration region 7p, the crystal recovery occurs particularly more effectively than the area of the anode region 8p not located on the side of the low-impurity-concentration region 7p. Thus, this area of the anode region 8p on the side of the low-impurity-concentration region 7p is formed into an area having a relatively high degree of crystallinity (high crystallinity anode region 4p). The high crystallinity anode region 4p is an area which is adjacent to the low-impurity-concentration region 7n or the low-impurity-concentration region 7p, and which has a higher degree of crystallinity than the degree of crystallinity of the region (for example, the central portion of the anode region 8p) that is not adjacent to the low-impurity-concentration region 7n or the low-impurity-concentration region 7p. In this way, the high crystallinity anode region 4p is an area which is adjacent to the low-impurity-concentration region 7n or the low-impurity-concentration region 7p, and which has a relatively high crystallinity in the anode region 8p.

Further, in the present embodiment, the cathode electrode 9n is provided to be in contact with the area of the cathode region 8n within 3 μm from the boundary at which the cathode region 8n is in contact with the low-impurity-concentration region 7n, and hence the cathode electrode 9n can be more surely brought into contact with the high crystallinity cathode region 4n. Therefore, the contact resistance between the cathode region 8n and the cathode electrode 9n is further reduced, so that the contact failure and the Iₒₙ failure can be further suppressed.

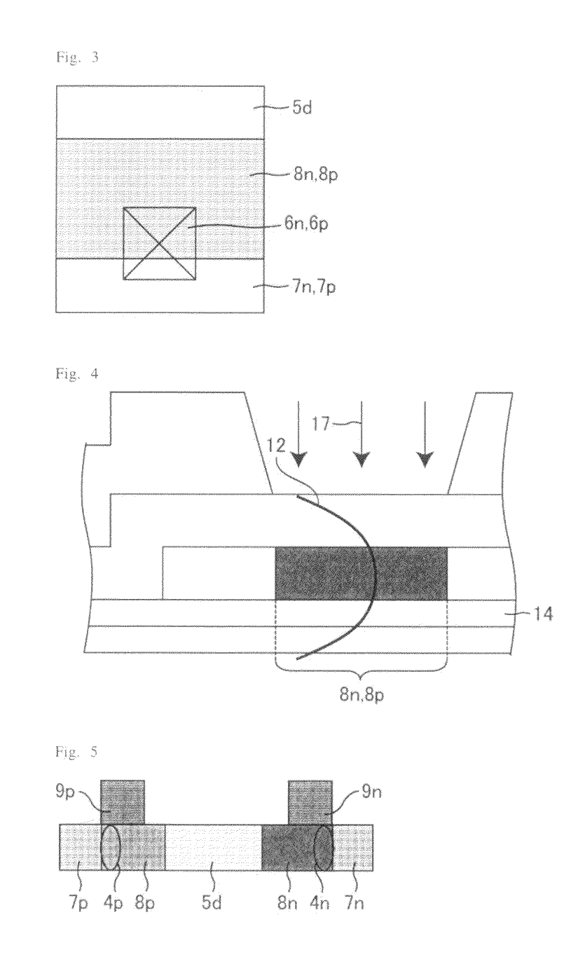

Further, as shown in FIG. 2(b) and FIG. 3, the cathode electrode 9n is arranged to cross over the boundary line between the cathode region 8n and the low-impurity-concentration region 7n, so as to be in contact with both the cathode region 8n and the low-impurity-concentration region 7n. That is, a part of the contact section 6n is arranged so as to overlap the low-impurity-concentration region 7n. Therefore, even if an alignment deviation occurs at the time of forming the contact hole for connecting the cathode electrode 9n, the cathode electrode 9n can be more surely arranged in the area of the cathode region 8n in which area the crystal recovery is sufficient. That is, even if a production apparatus having low alignment accuracy is used, the contact resistance can be more surely reduced, so that the contact failure and the Iₒₙ failure can be more surely suppressed.

Similarly, in the present embodiment, the anode electrode 9p is provided to be in contact with the area of the anode region 8p within 3 μm from the boundary at which the anode region 8p is in contact with the low-impurity-concentration region 7p, and hence the anode electrode 9p can be more surely brought into contact with the high crystallinity anode region 4p. Therefore, the contact resistance between the anode region 8p and the anode electrode 9p is further reduced, so that the contact failure and the Iₒₙ failure can be further suppressed.

Further, as shown in FIG. 2(b) and FIG. 3, the anode electrode 9p is arranged to cross over the boundary line between the anode region 8p and the low-impurity-concentration region 7p, so as to be in contact with both the anode region 8p and the low-impurity-concentration region 7p. That is, a part of the contact section 6p is arranged so as to overlap the low-impurity-concentration region 7p. Therefore, even if an alignment deviation occurs at the time of forming the contact hole for connecting the anode electrode 9p, the anode electrode 9p can be more surely arranged in the area of the anode region 8p in which area the crystal recovery is sufficient. That is, even if a production apparatus having low alignment accuracy is used, the contact resistance can be more surely reduced, so that the contact failure and the Iₒₙ failure can be more surely suppressed.

In the case where a part of each of the contact sections 6n and 6p is made to overlap each of the low-impurity-concentration regions 7n and 7p, respectively, the low-impurity-concentration regions 7n and 7p may overlap a region of about 80% or less of the respective contact sections 6n and 6p. The ratio of the region of the contact section 6n overlapping the low-impurity-concentration region 7n and the ratio of the region of the contact section 6p overlapping the low-impurity-concentration region 7p may be approximately equal to each other or may be different from each other.

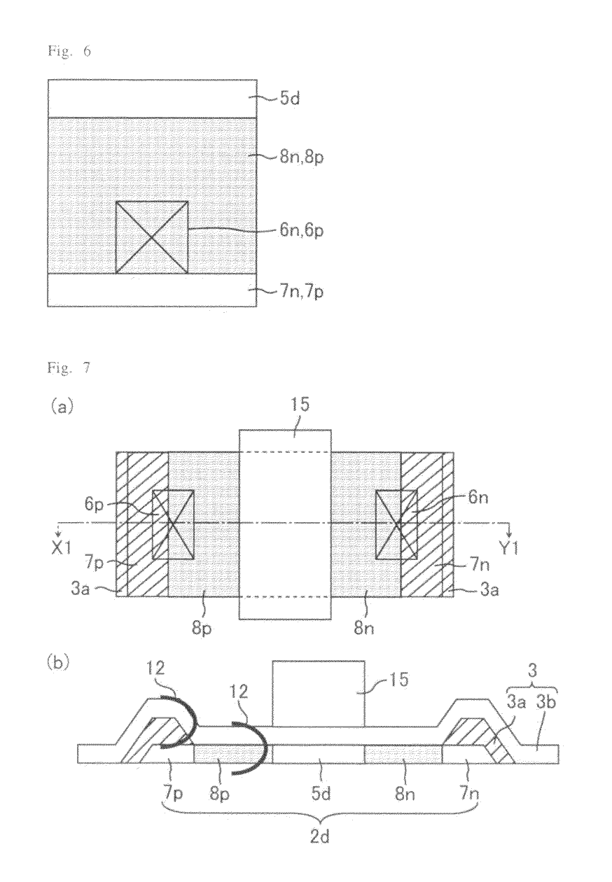

Meanwhile, as shown in FIGS. 5 and 6, the cathode electrode 9n may be provided so as not to be in contact with the low-impurity-concentration region 7n but so as to be in contact with the area of the cathode region 8n within 3 μm from the boundary at which the cathode region 8n is in contact with the low-impurity-concentration region 7n. Further, the cathode electrode 9n may be provided so as not to be in contact with the low-impurity-concentration region 7n but so as to be in contact with the high crystallinity cathode region 4n on the side of the cathode region 8n. Also with this configuration, the contact failure and the Iₒₙ failure can be suppressed.

Similarly, as shown in FIGS. 5 and 6, the anode electrode 9p may be provided so as not to be in contact with the low-impurity-concentration region 7p but so as to be in contact with the area of the anode region 8p within 3 μm from the boundary at which the anode region 8p is in contact with the low-impurity-concentration region 7p. Further, the anode electrode 9p may be provided so as not to be in contact with the low-impurity-concentration region 7p but so as to be in contact with the high crystallinity cathode region 4p on the side of the anode region 8p.

Further, as shown in FIG. 3, the first low-impurity-concentration region 7n is arranged so as to be adjacent to the cathode region 8n except the region of the cathode region 8n on the channel region 5d (anode region 8p) side, and thereby the reduction in the current amount of the TFD 100d due to the first low-impurity-concentration region 7n can be almost surely prevented. From this viewpoint, it is preferred that the first low-impurity-concentration region 7n is arranged in the region outside the current path between the cathode region 8n and the anode region 8p (in the region other than the region functioning as an LDD described below).

Similarly, the second low-impurity-concentration region 7p is arranged so as to be adjacent to the anode region 8p except the region of the anode region 8p on the channel region 5d (cathode region 8n) side, and thereby the reduction in the current amount of the TFD 100d due to the second low-impurity-concentration region 7p can be almost surely prevented. From this viewpoint, it is preferred that the second low-impurity-concentration region 7p is arranged in the region outside the current path between the cathode region 8n and the anode region 8p (in the region other than the region functioning as an LDD described below).

In the following, the other modification examples of the present embodiment will be described.

### Modification Example 1

The low-impurity-concentration regions 7n and 7p may be formed by utilizing the difference in the thickness of the insulating film 3. That is, as shown in FIGS. 7(a) and 7(b), on the low-impurity-concentration regions 7n and 7p, the insulating film 3 may be configured by stacking a first insulating film 3a and a second insulating film 3b, while on the channel region 5d, the cathode region 8n, and the anode region 8p, the insulating film 3 may be configured only by the second insulating film 3b. In this way, the insulating film 3 may be configured to have a film thickness difference. In the following, a method for forming the insulating film 3 having the film thickness difference and for forming the channel region 5d, the cathode region 8n, and the anode region 8p will be described.

First, the insulating film 3a having a film thickness of 20 to 200 nm (preferably 20 to 80 nm, for example, 50 nm) is formed so as to cover the crystalline semiconductor layer 2d. Next, a photoresist is patterned to mask the region of the first insulating film 3a under which region the low-impurity-concentration regions 7n and 7p are to be formed. The unmasked region of the first insulating film 3a is then removed by wet etching using hydrogen fluoride (HF), or the like. Thereby, an opening section (region in which the crystalline semiconductor layer 2d is exposed) of the first insulating film 3a is formed in the region including a part of the contact sections 6n and 6p.

Next, after the photoresist is removed, the second insulating film 3b having a film thickness of 20 to 200 nm (preferably 20 to 80 nm, for example, 30 nm) is formed so as to cover the crystalline semiconductor layer 2d and the first insulating film 3a. Thereby, the insulating film 3 is formed only by the second insulating film 3b in the opening section of the first insulating film 3a, while the insulating film 3 has a structure formed by stacking the first insulating film 3a and the second insulating film 3b in the region other than the opening section of first insulating film 3a, that is, in the region in which the low-impurity-concentration regions 7n and 7p are to be formed.

When the insulating film 3 is configured to have the film thickness difference in this way, and when a high dose of impurities are doped by the ion implantation method into the crystalline semiconductor layer 2d through the insulating film 3, the concentration of the impurities doped into the crystalline semiconductor layer 2d is different for each of the regions having different film thicknesses of the insulating film 3. Thus, the peak of the depth profile 12 of the doped impurities exists at different positions for each of the regions. As a result, the cathode region 8n, the anode region 8p, and the low-impurity-concentration regions 7n and 7p can be formed in the crystalline semiconductor layer 2d.

More specifically, as shown in FIG. 7(b), in the region of the crystalline semiconductor layer 2d, the region overlapping the region of the insulating film 3 having a large film thickness formed of the first insulating film 3a and the second insulating film 3b stacked one another, the amount of doped impurities is small. Hence, the low-impurity-concentration regions 7n and 7p are formed. Meanwhile, in the region of the crystalline semiconductor layer 2d overlapping the region of the insulating film 3 having a small film thickness formed only of the first insulating film 3a, the amount of doped impurities is large. Hence, the cathode region 8n and the anode region 8p are formed after activation. In this way, the first insulating film 3a only needs to be formed in the region on the crystalline semiconductor layer 2d excluding at least the region in which the cathode region 8n and the anode region 8p are to be formed, and including at least the region in which the low-impurity-concentration regions 7n and 7p are to be formed.

In order to form the channel region 5d, the doping of impurities only needs to be performed with a photoresist 15 formed and patterned only in the region where the channel region 5d is to be formed.

Further, in the embodiment shown in FIG. 7, the low-impurity-concentration regions 7n and 7p are formed by using the thickness difference provided by stacking the first insulating film 3a and the second insulating film 3b. On the other hand, the low-impurity-concentration regions 7n and 7p may be formed by utilizing a film thickness difference provided in one continuous insulating film. As a method for providing the film thickness difference in one continuous insulating film in this way, for example, a method for forming a LOCOS (Local Oxidation of Silicon) oxide film can be used.

Further, the low-impurity-concentration regions 7n and 7p may be formed by providing one continuous insulating film with a film quality difference and utilizing the film quality difference. A method for providing the film quality difference in one continuous insulating film, includes, for example, a method in which a photoresist is selectively formed on the region of the insulating film 3 overlapping the region with the low-impurity-concentration regions 7n and 7p to be formed therein, and in which impurity ions, such as silicon (Si) ions and argon (Ar) ions, are then implanted into the insulating film 3 by using the photoresist as a mask.

Further, the low-impurity-concentration regions 7n and 7p may be formed by using both the film thickness difference and the film quality difference of the insulating film. Thereby, it is possible to reduce the amount of the impurities implanted into the region of the crystalline semiconductor layer 5d, in which region the low-impurity-concentration regions 7n and 7p are to be formed. Thus, the degree of crystal damage in the low-impurity-concentration regions 7n and 7p is reduced, so that the effect of promoting the crystal recovery in the cathode region 8n and the anode region 8p can be further enhanced.

### Modification Example 2

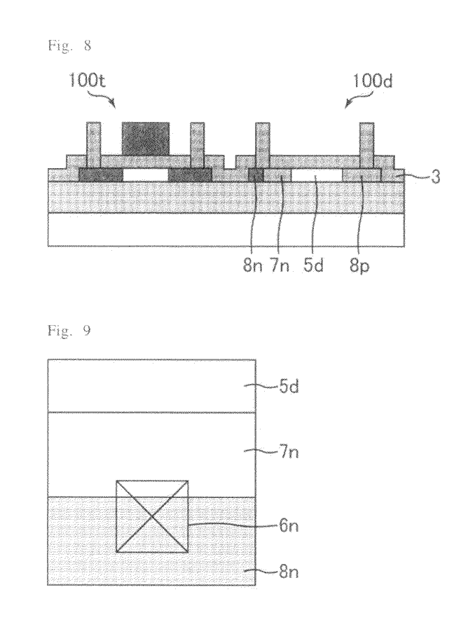

As shown in FIGS. 8 and 9, it is particularly preferred that the low-impurity-concentration region 7n is arranged between the cathode region 8n and the channel region 5d. That is, it is preferred in particular that the cathode region 8n, the low-impurity-concentration region 7n, and the channel region 5d are adjacently arranged in this order. Further, it is preferred in particular that the cathode region 8n, the low-impurity-concentration region 7n, the channel region 5d, and the anode region 8p are adjacently arranged in this order. Thereby, the low-impurity-concentration region 7n can be made to function similarly to the LDD (Lightly Doped Drain) in the TFT, and hence the leakage current can be suppressed. Meanwhile, in this specification, an embodiment, in which the low-impurity-concentration region is arranged between the cathode region and the anode region, and which functions similarly to the LDD in the TFT, is also referred to as an LDD structure.

Further, since the TFD 100d configured to function as a photo sensor needs to detect light, no gate electrode is provided on the TFD 100d (the region including the channel region 5d, and the low-impurity-concentration region 7n functioning similarly to the LDD in the TFT and/or the low-impurity-concentration region 7p functioning similarly to the LDD in the TFT described below). More preferably, in the TFD 100d having the LDD structure, a conductive layer (for example, a layer made of the same material as the material of the gate electrode 16) is not arranged in the region which is located between the crystalline semiconductor layer 2d and the layers of the cathode electrode 9n and the anode electrode 9p (in which the region in the contact hole is not, however, included), and which, in a plan view of the substrate 1, overlaps the crystalline semiconductor layer 2d. More specifically, in the TFD 100d having the LDD structure, a conductive layer existing immediately above the insulating film 3 and overlapping the crystalline semiconductor layer 2d is not provided. Therefore, the contact section 6n can be arranged close to the channel region 5d. In this way, from a viewpoint of making the layout of the TFD 100d as small as possible, the above described embodiment (LDD structure) is advantageous. The space between the crystalline semiconductor layer 2d and the layers of the cathode electrode 9n and the anode electrode 9p (in which the region in the contact hole is not, however, included) means an interlayer between the crystalline semiconductor layer 2d and wiring layers of the cathode electrode 9n and the anode electrode 9p (for example, the interlayer between the insulating film 3 and the interlayer insulating film).

On the other hand, the thin-film diode described in Patent Document 1 includes the gate electrode. Therefore, when the contact section is arranged close to the channel region, a short circuit may occur between the cathode electrode and the gate electrode and/or between the anode electrode and the gate electrode. Therefore, the reduction in the size of the layout of the thin-film diode is limited.

Further, in the thin-film diode having the LDD structure, for example, in the case where the gate electrode is partially arranged on the semiconductor layer, such as the case where the gate electrode is arranged only on the channel region except the region on the low-impurity-concentration region, the history of heat applied to the semiconductor layer, the efficiency of hydrogenation of the semiconductor layer, and the like, are made different by the presence or absence of the gate electrode, and thereby the optimum process condition may be different between the channel region and the low-impurity-concentration region. Therefore, in this case, it may become difficult to simultaneously improve the crystallinity of the channel region and of the low-impurity-concentration region. However, in the TFD 100d having the LDD structure according to the present embodiment, the conductive layer functioning as the gate electrode is not provided as described above. Therefore, even if the crystal recovery is achieved simultaneously in the channel region 5d and the low-impurity-concentration region (the low-impurity-concentration region 7n and/or the low-impurity-concentration region 7p) functioning similarly to the LDD, the good quality channel region 5d and the good quality low-impurity-concentration region functioning similarly to the LDD can be formed.

Note that, in the TFD 100d functioning as a photo sensor, only the contrast ratio needs to be secured. Therefore, the length (corresponding to the LDD length in the TFT) of the low-impurity-concentration region 7n functioning similarly to the LDD in the TFT (and the length of the low-impurity-concentration region 7p functioning similarly to the LDD in the TFT described below) can be set longer as compared with the LDD length in the TFT.

The TFD 100d having the LDD structure can be produced, for example, by the steps shown in FIG. 10. As shown in FIG. 10(a), a photoresist (resist) film is first formed, and the photoresist film is then patterned to remove the photoresist film above the crystalline semiconductor layer 2t and the photoresist film above the region in which the cathode region 8n and the low-impurity-concentration region 7n are to be formed. Thereby, a photoresist 15c is patterned on the region of the insulating film 3, the region overlapping the region in which the channel region 5d and the anode region 8p are to be formed.

Next, a low dose of impurities (pentavalent atoms, such as phosphorus atoms) 17 are doped into the crystalline semiconductor layers 2d and 2t through the insulating film 3 by using the photoresists 15c and the gate electrode 16 as masks. More specifically, phosphorus ions at a dose amount of 5×10¹¹ to 1×10¹⁵ cm⁻² (preferably 5×10¹² to 1×10¹⁴ cm⁻²) are doped as the impurities 17 by the ion implantation method at an acceleration voltage of 10 to 90 keV (preferably 30 to 70 keV). As a result, the impurities having a density of about 1×10¹⁴ to 1×10¹⁹ atm/cm³ (preferably, about 1×10¹⁵ to 1×10¹⁷ atm/cm³) are doped into the low-impurity-concentration region 7n. Further, the impurity concentration of the low-impurity-concentration region 7n in this embodiment is higher than the impurity concentration of the channel region 5d. That is, in the TFD 100d having the LDD structure, the impurity concentration of the low-impurity-concentration region 7n is set to an intermediate impurity concentration between the impurity concentration of the cathode region 8n and the impurity concentration of the channel region 5d. Thereafter, the photoresist 15c is removed.

Next, a photoresist (resist) film is formed as shown in FIG. 10(b), and the photoresist film is then patterned to remove the photoresist film above the crystalline semiconductor layer 2t and the photoresist film above the region in which the cathode region 8n is to be formed. Thereby, a photoresist 15d is patterned on the region of the insulating film 3 overlapping the region in which the low-impurity-concentration region 7n, the channel region 5d, and the anode region 8p are to be formed.

Then, the low-impurity-concentration region 7n can be formed between the cathode region 8n and the channel region 5d by performing the implantation step of doping a high dose of impurities and the activation treatment similarly to the method described above.

Also in this embodiment, as shown in FIG. 11, the cathode electrode 9n may not be in contact with the low-impurity-concentration region 7n, but may be in contact with the area of the cathode region 8n within 3 μm from the boundary at which the cathode region 8n is in contact with the low-impurity-concentration region 7n. Further, the cathode electrode 9n may not be in contact with the low-impurity-concentration region 7n, but may be in contact with the high crystallinity cathode region 4n on the side of the cathode region 8n.

On the other hand, in the embodiment shown in FIGS. 8 to 11, the low-impurity-concentration region 7p is not formed adjacent to the anode region 8p, and the anode electrode 9p is in contact with the anode region 8p. However, heavier impurities are usually doped in the cathode region 8n as compared with the anode region 8p, and hence the crystal damage proceeds more in the cathode region 8n. Therefore, as shown in FIGS. 8 to 11, even if the low-impurity-concentration region is formed only on the side of the cathode region 8n, the generation of contact failure can be suppressed to a level with no practical problem.

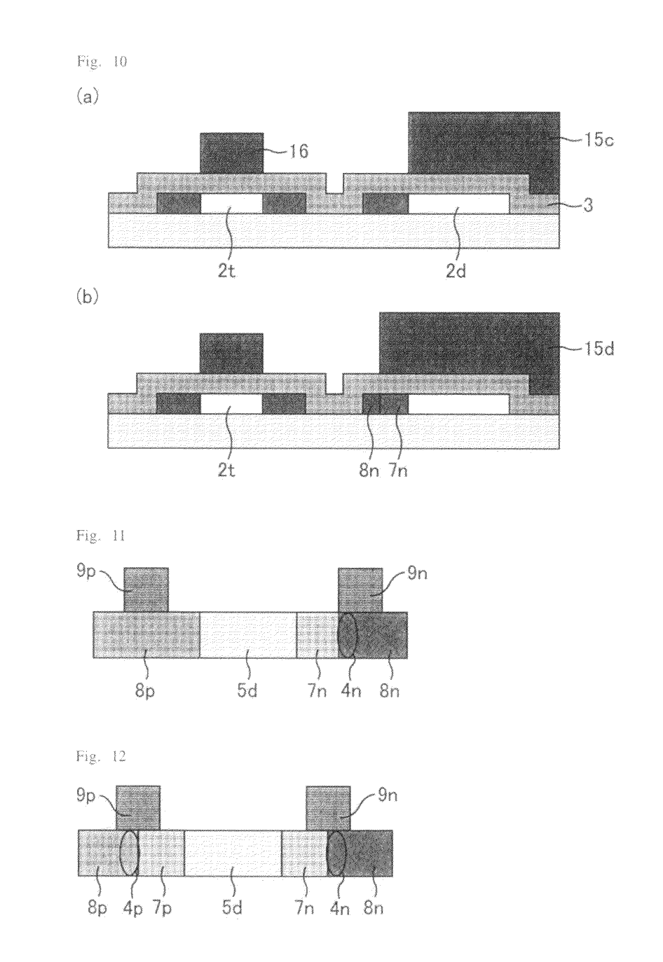

On the other hand, from the viewpoint of effectively suppressing the generation of contact failure, it is preferred that, also in the TFD 100d having the LDD structure, the low-impurity-concentration region functioning similarly to the LDD in the TFT is formed on both the cathode region 8n and the anode region 8p. More specifically, as shown in FIGS. 12 and 13, it is preferred that the cathode region 8n, the low-impurity-concentration region 7n, the channel region 5d, the anode region 8p, and the low-impurity-concentration region 7p are adjacently arranged in this order in the same plane.

At this time, the cathode electrode 9n need not be in contact with the low-impurity-concentration region 7n as shown in FIG. 13. However, as described above, from the viewpoint of more surely suppressing the contact failure and the Iₒₙ failure, it is preferred that the cathode electrode 9n is in contact with the low-impurity-concentration region 7n and the cathode region 8n as shown in FIG. 12, that the cathode electrode 9n is in contact with the area of the cathode region 8n within 3 μm from the boundary at which the cathode region 8n is in contact with the low-impurity-concentration region 7n, and that the cathode electrode 9n is in contact with the high crystallinity cathode region 4n.

On the other hand, when the cathode electrode 9n is not in contact with the low-impurity-concentration region 7n as shown in FIG. 13, it is preferred that the cathode electrode 9n is in contact with the area of the cathode region within 3 μm from the boundary at which the cathode region 8n is in contact with the low-impurity-concentration region 7n, and that the cathode electrode 9n is in contact with the high crystallinity cathode region 4n.

Similarly, the anode electrode 9p need not be in contact with the low-impurity-concentration region 7p as shown in FIG. 13. However, as described above, from the viewpoint of more surely suppressing the contact failure and the Iₒₙ failure, it is preferred that the anode electrode 9p is in contact with the low-impurity-concentration region 7p and the anode region 8p as shown in FIG. 12, that the anode electrode 9p is in contact with the area of the anode region 8p within 3 μm from the boundary at which the anode region 8p is in contact with the low-impurity-concentration region 7p, and that the anode electrode 9p is in contact with the high crystallinity cathode region 4p.

On the other hand, when the anode electrode 9p is not in contact with the low-impurity-concentration region 7p as shown in FIG. 13, it is preferred that the anode electrode 9p is in contact with the area of the anode region 8p within 3 μm from the boundary at which the anode region 8p is in contact with the low-impurity-concentration region 7p, and that the cathode electrode 9p is in contact with the high crystallinity cathode region 4p.

Note that, in this case, impurities (for example, boron ions) at a dose amount of 5×10¹¹ to 1×10¹⁵ cm⁻² (preferably 5×10¹² to 1×10¹⁴ cm⁻²) are doped into the low-impurity-concentration region 7p by the ion implantation method at an acceleration voltage of 10 to 90 keV (preferably 30 to 70 keV). As a result, the impurities having a density of about 1×10¹⁴ to 1×10¹⁹ atm/cm³ (preferably, about 1×10¹⁵ to 1×10¹⁷ atm/cm³) are doped into the low-impurity-concentration region 7p. Further, the impurity concentration of the low-impurity-concentration region 7p in this embodiment is higher than the impurity concentration of the channel region 5d. That is, in the TFD 100d having the LDD structure, the impurity concentration of the low-impurity-concentration region 7p is set to an intermediate impurity concentration between the impurity concentration of the anode region 8p and the impurity concentration of the channel region 5d.

### Modification Example 3

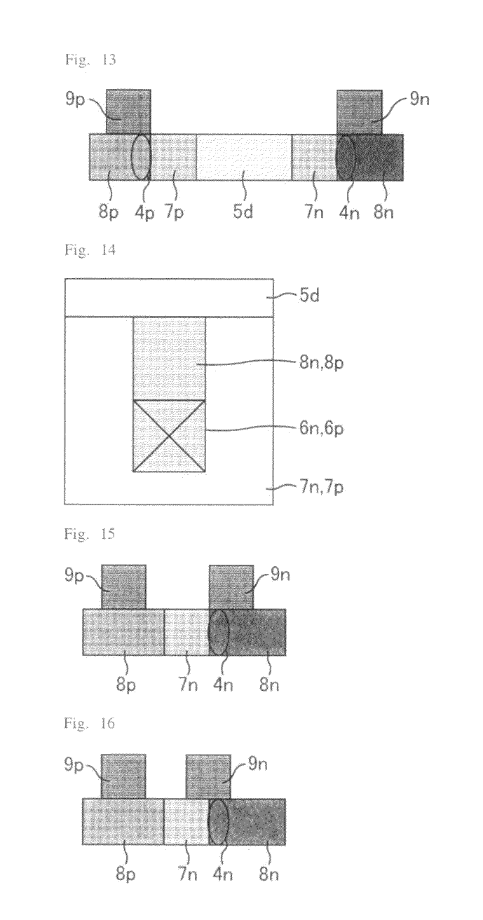

As shown in FIG. 14, in a plan view of the substrate 1, the low-impurity-concentration region 7n may be arranged along the outer periphery of the contact section 6n except the outer periphery of the contact section 6n on the side of the channel region 5d. Thereby, the crystal recovery of the cathode region 8n around the contact section 6n can be efficiently promoted, so that the contact resistance can be further reduced, and the contact failure and the Iₒₙ failure can be further suppressed. In this way, the low-impurity-concentration region 7n may be formed into a shape having a recess (for example, a U-shape) in a plan view, and the recessed portion may be arranged along the outer periphery of the contact section 6n.

Further, as shown in FIG. 14, in a plan view of the substrate 1, the low-impurity-concentration region 7n may be arranged along the current path between the contact section 6n and the channel region 5d, that is, along the region sandwiched between the contact section 6n and the contact section 6p. Thereby, the crystal recovery of the cathode region 8n around the current path between the contact section 6n and the channel region 5d can be promoted, so that the sheet resistance of the cathode region 8n serving as the current path between the contact section 6n and the channel region 5d can be reduced. Therefore, the contact failure and the Iₒₙ failure can be further suppressed. In this way, in a plan view of the substrate 1, the low-impurity-concentration region 7n may be arranged along the region sandwiched between the contact sections 6n and 6p which are arranged opposite to each other so as to sandwich the channel region 5d therebetween.

Further, as shown in FIG. 14, in a plan view of the substrate 1, the low-impurity-concentration region 7n may be arranged along the current path between the contact section 6n and the channel region 5d and along the outer periphery of the contact section 6n except the outer periphery of the contact section 6n on the side of the channel region 5d. Thereby, the crystal recovery of the cathode region 8n around the current path between the contact section 6h and the channel region 5d can be promoted, so that the sheet resistance of the cathode region 8n serving as the current path between the contact section 6n and the channel region 5d can be reduced. Further, the crystal recovery of the cathode region 8n around the contact section 6n can be efficiently promoted, and hence the contact resistance can be further reduced. From the above, the contact resistance is further reduced, and thereby the contact failure can be further suppressed. Further, the on-resistance of the semiconductor device can be further reduced, and the Iₒₙ failure can be further suppressed. In this way, in a plan view of the substrate 1, the low-impurity-concentration region 7n may be arranged along the region sandwiched between the contact sections 6n and 6p arranged opposite to each other so as to sandwich the channel region 5d therebetween, and may be arranged along the outer periphery of the contact section 6n except the outer periphery of the contact section 6n on the side of the channel region 5d.

Similarly, as shown in FIG. 14, in a plan view of the substrate 1, the low-impurity-concentration region 7p may be arranged along the outer periphery of the contact section 6p except the outer periphery of the contact section 6p on the side of the channel region 5d. The low-impurity-concentration region 7p may also be formed into a shape having a recess (for example, a U-shape) in a plan view, and the recessed portion may be arranged along the outer periphery of the contact section 6p.

Further, as shown in FIG. 14, in a plan view of the substrate 1, the low-impurity-concentration region 7p may be arranged along the current path between the contact section 6p and the channel region 5d, that is, along the region sandwiched between the contact section 6n and the contact section 6p. In this way, in a plan view of the substrate 1, the low-impurity-concentration region 7p may be arranged along the region sandwiched between the contact sections 6n and 6p which are arranged opposite to each other so as to sandwich the channel region 5d therebetween.

Further, as shown in FIG. 14, in a plan view of the substrate 1, the low-impurity-concentration region 7p may be arranged along the current path between the contact section 6p and the channel region 5d and along the outer periphery of the contact section 6p except the outer periphery of the contact section 6p on the side of the channel region 5d. In a plan view of the substrate 1, the low-impurity-concentration region 7p may be arranged along the region sandwiched between the contact sections 6n and 6p arranged opposite to each other so as to sandwich the channel region 5d therebetween, and may be arranged along the outer periphery of the contact section 6p except the outer periphery of the contact section 6p on the side of the channel region 5d.

Note that an embodiment in which the low-impurity-concentration regions 7n and 7p do not overlap the contact sections 6n and 6p is shown in FIG. 14, but at least a part of the contact sections 6n and 6p (preferably, a part of the outer periphery of the contact sections 6n and 6p, more preferably all portion of the outer peripheral section of the contact sections 6n and 6p except the outer peripheral section of the contact sections 6n and 6p on the side of the channel region 5d) may overlap the low-impurity-concentration regions 7n and 7p. Thereby, the contact failure and the Iₒₙ failure can be more surely suppressed.

### Modification Example 4

The TFD 100d may be a TFD having a PN structure. That is, the channel region 5d may be omitted in each of the embodiments described above.

Specifically, for example, as shown in FIG. 15, the cathode region 8n, the low-impurity-concentration region 7n, and the anode region 8p may be adjacently arranged in this order in the same plane.

At this time, the low-impurity-concentration region 7n is arranged between the cathode region 8n and the anode region 8p, and functions similarly to the LDD in the TFT.

Note that, similarly to the case of modification 2, phosphorus ions at a dose amount of 5×10¹¹ to 1×10¹⁵ cm⁻² (preferably 5×10¹² to 1×10¹⁴ cm⁻²) are doped as the impurities 17 into the low-impurity-concentration region 7n by the ion implantation method at an acceleration voltage of 10 to 90 keV (preferably 30 to 70 keV). As a result, the impurities having a density of about 1×10¹⁴ to 1×10¹⁹ atm/cm³ (preferably, about 1×10¹⁵ to 1×10¹⁷ atm/cm³) are doped into the low-impurity-concentration region 7n.

Further, the cathode electrode 9n may be in contact with the low-impurity-concentration region 7n, but from the viewpoint of preventing the short circuit between the cathode electrode 9n and the anode electrode 9p, it is preferred that the cathode electrode 9n is not in contact with the low-impurity-concentration region 7n as shown in FIG. 15.

However, from the viewpoint of more surely suppressing the contact failure and the Iₒₙ failure, it is preferred that the cathode electrode 9n is in contact with the area of the cathode region 8n within 3 μm from the boundary at which the cathode region 8n is in contact with the low-impurity-concentration region 7n, and that the cathode electrode 9n is in contact with the high crystallinity cathode region 4n.

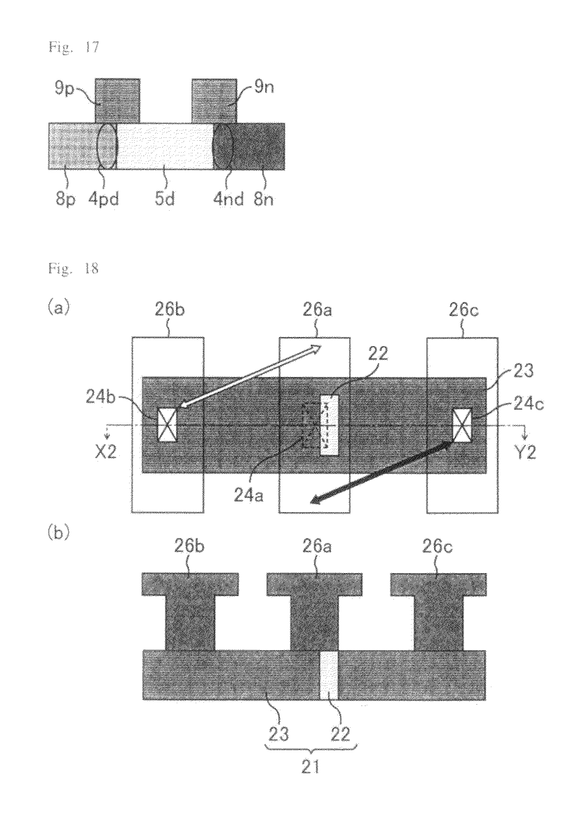

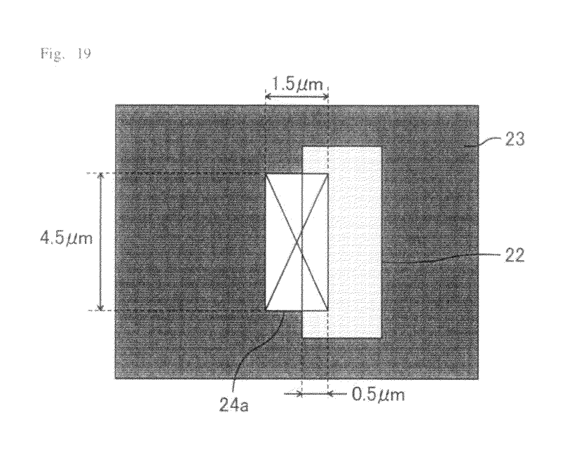

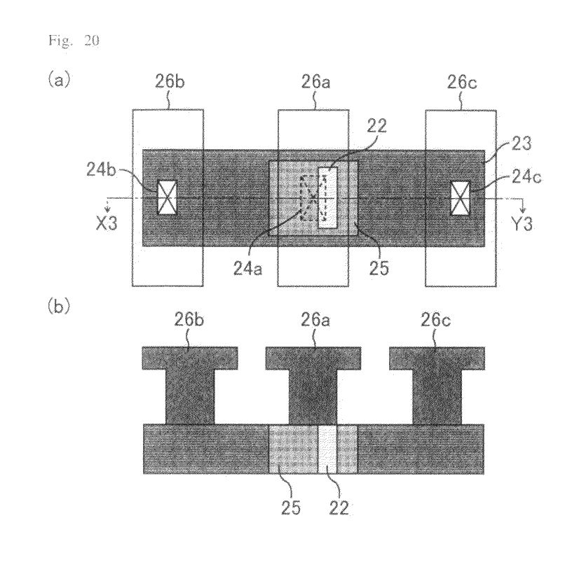

On the other hand, when the short circuit between the cathode electrode 9n and the anode electrode 9p need not be considered, from the viewpoint of more surely suppressing the contact failure and the Iₒₙ failure, the cathode electrode 9n may be arranged so as to be in contact with the low-impurity-concentration region 7n and the cathode region 8n as shown in FIG. 16.

On the other hand, in the embodiment shown in FIGS. 15 and 16, the low-impurity-concentration region 7p is not formed adjacent to the anode region 8p, and the anode electrode 9p is in contact with the anode region 8p. However, even in this embodiment, the generation of contact failure can be suppressed to a level with no practical problem, similarly to the case shown in FIGS. 8 to 11.

Of course, also in the PN structure, the low-impurity-concentration region 7p functioning similarly to the LDD in the TFT may also be provided. In this case, impurities (for example, boron ions) at a dose amount of 5×10¹¹ to 1×10¹⁵ cm⁻² (preferably 5×10¹² to 1×10¹⁴ cm⁻²) are doped by the ion implantation method at an acceleration voltage of 10 to 90 keV (preferably 30 to 70 keV). As a result, the impurities at a density of about 1×10¹⁴ to 1×10¹⁹ atm/cm³ (preferably, about 1×10¹⁵ to 1×10¹⁷ atm/cm³) are doped into the low-impurity-concentration region 7p.

### Modification Example 5

The channel region 5d is a no ion implantation region into which impurities are not doped, or a region containing a very slight amount of impurities. Therefore, the channel region 5d can also be used as a starting point of the crystal recovery. That is, when the cathode region 8n and the anode region 8p are adjacent to the channel region 5d, the crystallinity can be greatly improved also in the areas of the cathode region 8n and the anode region 8p, which areas are adjacent to the channel region 5d.

More specifically, in the area of the cathode region 8n within 2 μm from the boundary at which the cathode region 8n is in contact with the channel region 5d, the crystal recovery occurs particularly more effectively than the area of the cathode region 8n, the area being not located on the side of the channel region 5d. Thus, the area of the cathode region 8n on the side of the channel region 5d is formed to have relatively high crystallinity (high crystallinity cathode region 4nd). Note that the high crystallinity cathode region 4nd is a region which is adjacent to the channel region 5d, and which has crystallinity higher than the area of the cathode region 8n (for example, the central portion of the cathode region 8n), the area being not adjacent to the channel region 5d. In this way, the high crystallinity cathode region 4nd is a region which is adjacent to the channel region 5d and which has relatively high crystallinity in the cathode region 8n.

Similarly, in the area of the anode region 8n within 2 μm from the boundary at which the anode region 8p is in contact with the channel region 5d, the crystal recovery occurs particularly more effectively than the area of the anode region 8n, the area being not located on the side of the channel region 5d. Thus, the area of the anode region 8n on the side of the channel region 5d is formed to have relatively high crystallinity (high crystallinity anode region 4pd). The high crystallinity anode region 4pd is a region which is adjacent to the channel region 5d, and which has crystallinity higher than the area of the anode region 8p (for example, the central portion of the anode region 8p), the area being not adjacent to the channel region 5d. In this way, the high crystallinity anode region 4pd is a region which is adjacent to the channel region 5d and which has relatively high crystallinity in the anode region 8p.

Further, as shown in FIG. 17, the cathode region 8n, the channel region 5d, and the anode region 8p may be adjacently arranged in this order in the same plane in such a manner that the cathode electrode 9n is in contact with the area of the cathode region 8n within 3 μm from the boundary at which the cathode region 8n is in contact with the channel region 5d, and/or is in contact with the high crystallinity cathode region 4nd, and that the anode electrode 9p is in contact with the area of the anode region 8p within by 3 μm from the boundary at which the anode region 8p is in contact with the channel region 5d, and/or is in contact with the high crystallinity cathode region 4pd.

As described above, with embodiment 1, the sheet resistance of the cathode region 8n and the anode region 8p can be reduced, and the contact resistance of the crystalline semiconductor layer 2d with the cathode electrode 9n and the anode electrode 9p can be reduced, so that the generation of the contact failure can be suppressed.

Note that the various embodiments mentioned above may be employed in combination. Further, the semiconductor device of the present embodiment may include both the low-impurity-concentration region 7n and the low-impurity-concentration region 7p, or may include only one of the low-impurity-concentration region 7n and the low-impurity-concentration region 7p. For example, the semiconductor device of the present embodiment may include only the low-impurity-concentration region 7p without including the low-impurity-concentration region 7n.

Further, in the present embodiment, as long as the low-impurity-concentration region is arranged adjacent to the cathode region and/or the anode region, the arrangement place of the low-impurity-concentration region is not limited in particular, and the low-impurity-concentration region can be suitably arranged according to the layout of the device. For example, when the semiconductor device of the present embodiment includes both the low-impurity-concentration region 7n and the low-impurity-concentration region 7p, the semiconductor device may be configured such that one of the low-impurity-concentration region 7n and the low-impurity-concentration region 7p is arranged between the cathode region and the anode region, and such that the other is not arranged between the cathode region and the anode region. That is, the semiconductor device may be configured such that one region is made to function as the LDD in the TFT, and such that the other region is not made to function as the LDD in the TFT.

Further, in the present embodiment, the arrangement of the cathode electrode and the anode electrode is also not limited in particular, and may be suitably set according to the layout of the device. Therefore, the cathode electrode may be or may not be in contact with the low-impurity-concentration region. Further, also the anode electrode may be or may not be in contact with the low-impurity-concentration region. For example, when the semiconductor device of the present embodiment includes the low-impurity-concentration region 7n and the low-impurity-concentration region 7p, the semiconductor device may be configured such that one of the cathode electrode and the anode electrode is in contact with one of the low-impurity-concentration region 7n and the low-impurity-concentration region 7p, and such that the other one of the cathode electrode and the anode electrode is not in contact with any of the low-impurity-concentration region 7n and the low-impurity-concentration region 7p.

In this way, in the present embodiment, according to the layout of the device and the performance required for the device, it is possible to suitably change the states of various selections, such as the selection on whether or not the low-impurity-concentration region is provided in correspondence with both the cathode region and the anode region, the selection on whether or not the configuration on the side of the cathode region and the configuration on the side of the anode region are formed similarly to each other, the selection on whether or not the low-impurity-concentration region is made to function similarly to the LDD in the TFT, and the selection on whether or not the cathode electrode and the anode electrode are in contact with the low-impurity-concentration region.

The variations in the production step which influence the crystal recovery of the semiconductor layer include a variation in the film thickness of the insulating film, a variation in the film thickness of the semiconductor layer, a variation in the implantation of impurities, a variation in the activation, and the like. In the following, there will be described the results of verification of the effects of the present invention in the case where damage of a semiconductor layer was intentionally increased by excessively implanting impurities into the semiconductor layer. Specifically, an element for contact resistance measurement into which impurities were implanted under the normal condition, and an element for contact resistance measurement into which the impurities were excessively implanted were produced, and the contact resistances of the contact section of the elements were measured by a four-terminal method so as to be compared with each other.

### Example 1

As shown in FIG. 18, the element for contact resistance measurement of example 1 includes a crystalline semiconductor layer 21 formed on a substrate (not shown), an insulating film (not shown) formed on the crystalline semiconductor layer 21, and electrodes 26a, 26b, and 26c formed on the insulating film.

The crystalline semiconductor layer 21 includes a low-impurity-concentration region 22 with no impurity implanted therein, and a high concentration impurity region 23 with a high dose of phosphorus ions doped therein by the ion implantation method. The implantation conditions (standard conditions) for the high concentration impurity region 23 were set such that the acceleration voltage was 20 keV and the dose amount was 8×10¹⁴ cm⁻².

Through the contact hole provided in the insulating film, the electrode 26a is in contact with the low-impurity-concentration region 22 and the high concentration impurity region 23. As shown in FIG. 19, the size of a contact section 24a of the crystalline semiconductor layer 21 in contact with the electrode 26a was set to the longitudinal size of 4.5 μm×the lateral size of 1.5 μm, and the width of the area of the low-impurity-concentration region 22, the area overlapping the contact section 24a, was set to 0.5 μm. That is, the contact hole was arranged so as to make the one third of the contact section 24a overlap the low-impurity-concentration region 22.

In contrast, the electrodes 26b and 26c were made to be in contact only with the high concentration impurity region 23 (contact sections 24b and 24c) through the contact holes provided in the insulating film.

Then, the contact resistance was obtained by measuring the potential difference between the electrode 26a and the electrode 26c shown by the black arrow in FIG. 18 while permitting current flow between the electrode 26a and the electrode 26b shown by the hollow arrow in FIG. 18.

### Example 2

The element for contact resistance measurement of example 2 has the same configuration as the configuration of the element for contact resistance measurement of example 1 except that an excessive implantation region is provided.

As shown in FIG. 20, an excessive implantation region 25 with phosphorus excessively doped therein by the ion implantation method was formed so as to overlap the contact section 24a (except the low-impurity-concentration region 22), and so as not overlap the contact sections 24b and 24c of the crystalline semiconductor layer 21 which are in contact with the electrodes 26b and 26c.

Phosphorus was implanted into the excessive implantation region 25 under the standard conditions, and then phosphorus was additionally implanted into the excessive implantation region 25 under the conditions of the acceleration voltage of 45 keV and the dose amount of 8×10¹⁵ cm⁻² (excessive implantation conditions).

### Comparative Example 1

As shown in FIG. 21, the element for contact resistance measurement of comparative example 1 has the same configuration as the configuration of the element for contact resistance measurement of example 1 except that the low-impurity-concentration region 22 is not provided.

### Comparative Example 2

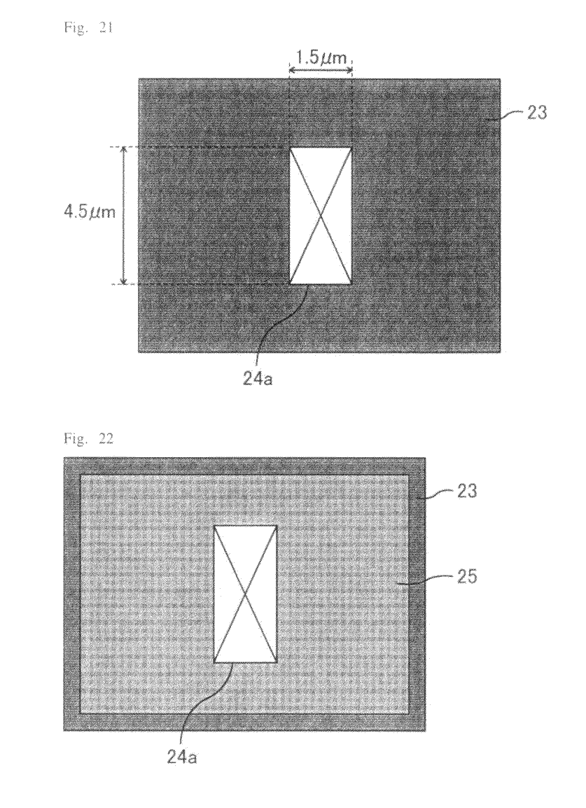

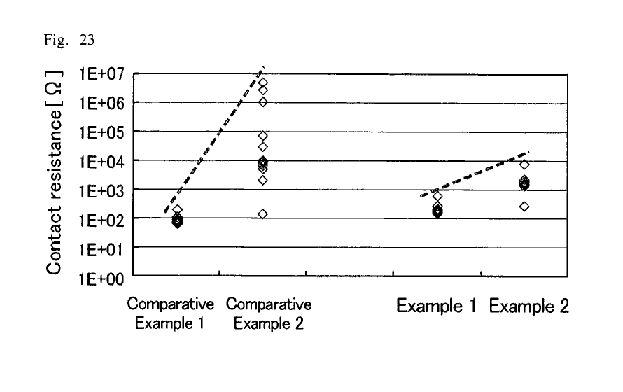

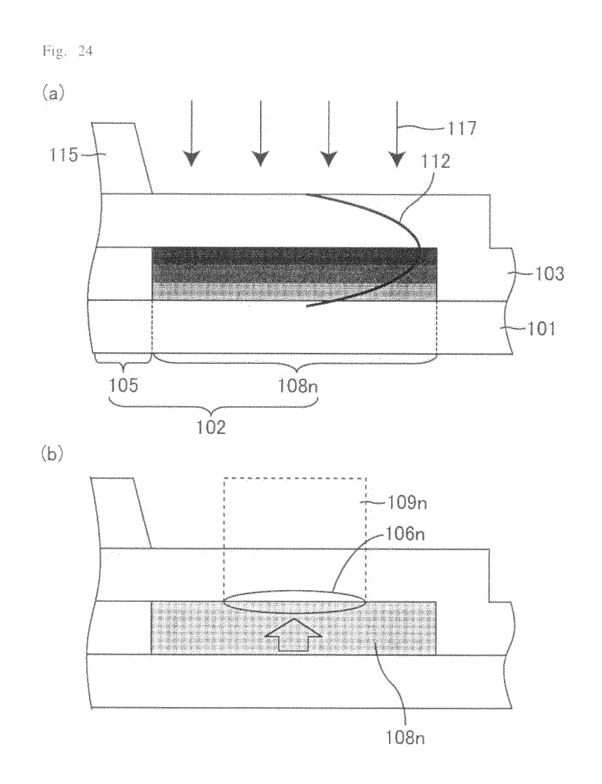

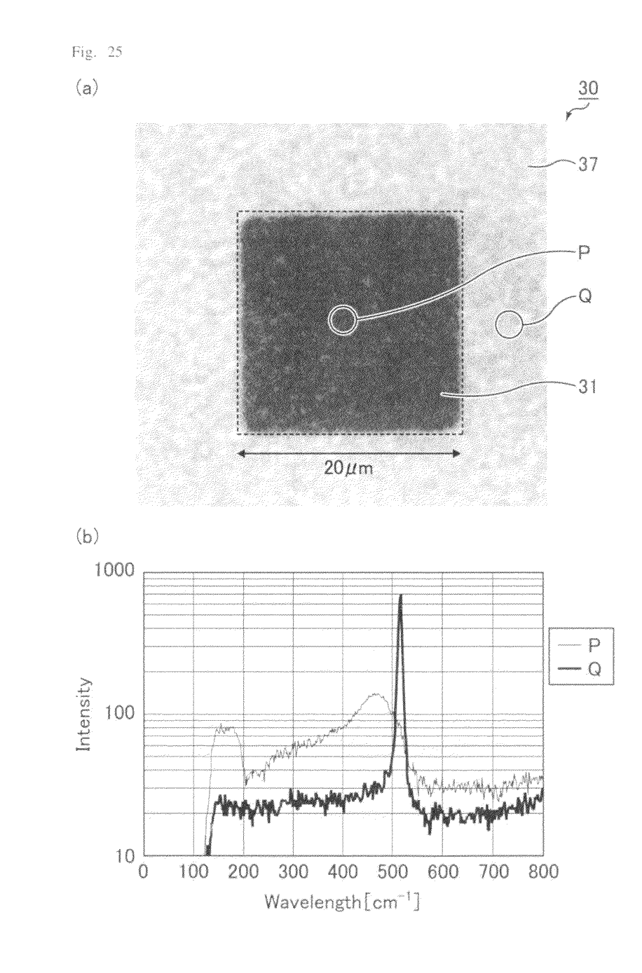

As shown in FIG. 22, the element for contact resistance measurement of comparative example 2 has the same configuration as the configuration of the element for contact resistance measurement of example 2 except that the low-impurity-concentration region 22 is not provided.

The contact resistances of examples 1 and 2, and comparative examples 1 and 2 are shown in FIG. 23. The contact resistances were measures by using a plurality of elements produced for each of examples 1 and 2, and for each of comparative examples 1 and 2.

From the results of comparative examples 1 and 2, it was found that, in the case where the low-impurity-concentration region 22 is not arranged in the vicinity of the contact section 24a, when impurities are excessively implanted, the contact resistance is increased. That is, the element not provided with the low-impurity-concentration region 22 has a small margin against the variation in the production step.

On the other hand, from the results of examples 1 and 2, it was found that, in the case where the low-impurity-concentration region 22 is arranged under the contact section 24a so as to overlap the contact section 24a, the increase of the contact resistance due to the excessive implantation of impurities can be significantly suppressed.

Note that, in example 1 provided with the low-impurity-concentration region 22 overlapping the contact section 24a, the contact resistance becomes slightly higher than the contact resistance in comparative example 1 not provided with the low-impurity-concentration region 22. However, the contact resistance under the normal conditions can also be reduced by increasing the area of the contact section 24a while securing the process margin. Specifically, for example, the size of the contact section 24a may be set to the longitudinal size of 4.5 μm×the lateral size of 2 μm, and the size of the area of the low-impurity-concentration region 22, the area overlapping the contact section 24a, may be set to the longitudinal size of 4.5 μm×the lateral size of 0.5 μm.

The present application claims priority to Patent Application No. 2009-063147 filed in Japan on Mar. 16, 2009 under the Paris Convention and provisions of national law in a designated State, the entire contents of which are hereby incorporated by reference.

### DESCRIPTION OF SYMBOLS

1, 101: Substrate
2d, 2t, 102: Crystalline semiconductor layer
3, 103: Insulating film
3a: First insulating film
3b: Second insulating film
4n, 4nd: High crystallinity cathode region
4p, 4pd: High crystallinity anode region
5d, 5t, 105: Channel region
6n, 6p, 106n: Contact section
7n, 7p: Low-impurity-concentration region
8n, 108n: Cathode region
8p: Anode region
9n, 109n: Cathode electrode
9p: Anode electrode
10a, 10b: Source/drain electrode
11a, 11b: Source/drain region
12, 112: Depth profile
14: Underlayer
15, 15a, 15b, 15c, 15d, 115: Photoresist (resist)
16: Gate electrode
17, 117: Impurity
21: Crystalline semiconductor layer
22: Low-impurity-concentration region
23: High concentration impurity region
24a, 24b, 24c: Contact section
25: Excessive implantation region
26a, 26b, 26c: Electrode
30: Polysilicon
31: Ion implantation region
33: Amorphous silicone
37: No ion implantation region
100d: TFD
100t: TFT

1. A semiconductor device comprising a thin-film diode including a crystalline semiconductor layer which includes a cathode region and an anode region; a cathode electrode connected to the cathode region; and an anode electrode connected to the anode region, the thin film diode, the cathode electrode, and the anode electrode being disposed on a substrate,
wherein the crystalline semiconductor layer includes a first low-impurity-concentration region having an impurity concentration lower than the impurity concentration of the cathode region,
the first low-impurity-concentration region is arranged adjacent to the cathode region, and
the cathode electrode is in contact with an area of the cathode region, the area being within 3 m from the boundary at which the cathode region is in contact with the first low-impurity-concentration region.

2. The semiconductor device according to claim 1, wherein the first low-impurity-concentration region and the cathode region are arranged in a same plane.

3. The semiconductor device according to claim 1, wherein the first low-impurity-concentration region is arranged between the cathode region and the anode region.

4. The semiconductor device according to claim 3,
wherein the thin-film diode includes a first insulating layer provided on the crystalline semiconductor layer, and a second insulating layer provided on the first insulating layer,
the cathode electrode and the anode electrode are provided on the second insulating layer, and
the thin-film diode does not include a conductive layer provided immediately above the first insulating layer and overlaps the crystalline semiconductor layer.

5. The semiconductor device according to claim 2,
wherein the crystalline semiconductor layer includes a first contact section which is a portion in contact with the cathode electrode, and
the first low-impurity-concentration region is arranged along the outer periphery of the first contact section except the outer periphery of the first contact section on the anode region side in a plan view of the substrate.

6. The semiconductor device according to claim 2,
wherein the crystalline semiconductor layer includes a first contact section which is a portion in contact with the cathode electrode, and
the first low-impurity-concentration region is arranged along a current path between the first contact section and the anode region in a plan view of the substrate.

7. The semiconductor device according to claim 2,
wherein the crystalline semiconductor layer includes a first contact section which is a portion in contact with the cathode electrode, and
the first low-impurity-concentration region is arranged along a current path between the first contact section and the anode region, and is arranged along the outer periphery of the first contact section except the outer periphery of the first contact section on the anode region side in a plan view of the substrate.

8. The semiconductor device according claim 2, further comprising:
an insulating film provided on the crystalline semiconductor layer; and
a first resist provided on a region of the insulating film, the region overlapping the first low-impurity-concentration region.

9. The semiconductor device according to claim 2, further comprising
an insulating film provided on the crystalline semiconductor layer,
wherein a region of the insulating film overlapping the first low-impurity-concentration region is connected to a region of the insulating film overlapping the cathode region and
at least one of the film thickness and the film quality of the insulating film is different between the region of the insulating film overlapping the first low-impurity-concentration region and the region of the insulating film overlapping the cathode region.

10. The semiconductor device according to claim 2, further comprising
an insulating film provided on the crystalline semiconductor layer,
wherein a region of the insulating film overlapping the first low-impurity-concentration region includes a plurality of stacked insulating films.

11. The semiconductor device according to claim 1, wherein the crystalline semiconductor layer includes a channel region arranged between the anode region and the cathode region.

12. The semiconductor device according to claim 1, wherein the crystalline semiconductor layer does not include a channel region arranged between the anode region and the cathode region.

13. A production method of the semiconductor device according to claim 8, the production method comprising the steps of:
patterning the first resist on the insulating film; and
adding impurities to the crystalline semiconductor layer through the insulating film by using the first resist as a mask.

14. A production method of the semiconductor device according to claim 10, the production method comprising the steps of:
patterning a first insulating film on the region in which the first low-impurity-concentration region of the crystalline semiconductor layer is to be formed;
covering the crystalline semiconductor layer and the first insulating film to form a second insulating film; and
adding impurities to the crystalline semiconductor layer through the first insulating film and the second insulating film.

15. A display device comprising the semiconductor device according to claim 1.

16. A display device comprising a semiconductor device produced by the production method of the semiconductor device according to claim 13.

17. A semiconductor device comprising a thin-film diode including a crystalline semiconductor layer which includes a cathode region and an anode region; a cathode electrode connected to the cathode region; and an anode electrode connected to the anode region, the thin film diode, the cathode electrode, and the anode electrode being disposed on a substrate,
wherein the crystalline semiconductor layer includes a second low-impurity-concentration region having an impurity concentration lower than the impurity concentration of the anode region,
the second low-impurity-concentration region is arranged adjacent to the anode region, and
the anode electrode is in contact with an area of the anode region, the area being within 3 m from the boundary at which the anode region is in contact with the second low-impurity-concentration region.

18. A display device comprising the semiconductor device according to claim 17.

19. A semiconductor device comprising a thin-film diode including a crystalline semiconductor layer which includes a cathode region and an anode region; a cathode electrode connected to the cathode region; and an anode electrode connected to the anode region, the thin film diode, the cathode electrode, and the anode electrode being disposed on a substrate,
wherein the crystalline semiconductor layer includes a first low-impurity-concentration region having an impurity concentration lower than the impurity concentration of the cathode region,
the first low-impurity-concentration region is arranged adjacent to the cathode region, and
the cathode electrode is in contact with the cathode region and the first low-impurity-concentration region.

20. A display device comprising the semiconductor device according to claim 19.

21. A semiconductor device comprising a thin-film diode including a crystalline semiconductor layer which includes a cathode region and an anode region; a cathode electrode connected to the cathode region; and an anode electrode connected to the anode region, the thin film diode, the cathode electrode, and the anode electrode being disposed on a substrate,
wherein the crystalline semiconductor layer includes a second low-impurity-concentration region having an impurity concentration lower than the impurity concentration of the anode region,
the second low-impurity-concentration region is arranged adjacent to the anode region, and
the anode electrode is in contact with the anode region and the second low-impurity-concentration region.

22. A display device comprising the semiconductor device according to claim 21.

23. A semiconductor device comprising a thin-film diode including a crystalline semiconductor layer which includes a cathode region and an anode region; a cathode electrode connected to the cathode region; and an anode electrode connected to the anode region, the thin film diode, the cathode electrode, and the anode electrode being disposed on a substrate,
wherein the crystalline semiconductor layer includes a first low-impurity-concentration region having an impurity concentration lower than the impurity concentration of the cathode region,
the first low-impurity-concentration region is arranged adjacent to the cathode region,
the cathode region includes a high crystallinity cathode region which is located on the side of the first low-impurity-concentration region and has crystallinity higher than the crystallinity of an area of the cathode region not located on the side of the first low-impurity-concentration region, and
the cathode electrode is in contact with the high crystallinity cathode region.

24. A display device comprising the semiconductor device according to claim 23.

25. A semiconductor device comprising a thin-film diode including a crystalline semiconductor layer which includes a cathode region and an anode region; a cathode electrode connected to the cathode region; and an anode electrode connected to the anode region, the thin film diode, the cathode electrode, and the anode electrode being disposed on a substrate,
wherein the crystalline semiconductor layer includes a second low-impurity-concentration region having an impurity concentration lower than the impurity concentration of the anode region,
the second low-impurity-concentration region is arranged adjacent to the anode region,
the anode region includes a high crystallinity anode region which is located on the side of the second low-impurity-concentration region and has crystallinity higher than the crystallinity of an area of the anode region not located on the side of the second low-impurity-concentration region, and
the anode electrode is in contact with the high crystallinity anode region.

26. A display device comprising the semiconductor device according to claim 25.

27. A semiconductor device comprising a thin-film diode including a crystalline semiconductor layer which includes a cathode region and an anode region; a cathode electrode connected to the cathode region; and an anode electrode connected to the anode region, the thin film diode, the cathode electrode, and the anode electrode being disposed on a substrate,
wherein the crystalline semiconductor layer includes a first low-impurity-concentration region having an impurity concentration lower than the impurity concentration of the cathode region, and
the first low-impurity-concentration region is arranged adjacent to the cathode region except the region of the cathode region on the anode region side.

28. A display device comprising the semiconductor device according to claim 27.

29. A semiconductor device comprising a thin-film diode including a crystalline semiconductor layer which includes a cathode region and an anode region; a cathode electrode connected to the cathode region; and an anode electrode connected to the anode region, the thin film diode, the cathode electrode, and the anode electrode being disposed on a substrate,
wherein the crystalline semiconductor layer includes a second low-impurity-concentration region having an impurity concentration lower than the impurity concentration of the anode region, and
the second low-impurity-concentration region is arranged adjacent to the anode region except the region of the anode region on the cathode region side.

30. A display device comprising the semiconductor device according to claim 29.
